(19) United States
(12) Patent Application Publication
(10) Pub. No.: US 2026/0297345 A1
(43) Pub. Date: Oct. 1, 2026

(54) PHOTOPOLYMERIZABLE COMPOSITION AND ELECTRONIC DEVICE

(71) Applicant: DONGJIN SEMICHEM CO., LTD., Incheon (KR)

(72) Inventors: Sung Min CHO, Hwaseong-si, Gyeonggi-do (KR); Hyoc Min YOUN, Hwaseong-si, Gyeonggi-do (KR); Tai Hoon YEO, Hwaseong-si, Gyeonggi-do (KR); Sang Hoon LEE, Hwaseong-si, Gyeonggi-do (KR); Jong Hyuk PARK, Hwaseong-si, Gyeonggi-do (KR); Sang Min LEE, Hwaseong-si, Gyeonggi-do (KR)

(21) Appl. No.: 19/479,306

(22) PCT Filed: May 7, 2024
(86) PCT No.: PCT/KR2024/006061

§ 371 Date: Oct. 27, 2025

(30) Foreign Application Priority Data
May 18, 2023 (KR) 10-2023-0064317
May 3, 2024 (KR) 10-2024-0059023

(51) Int. Cl. C09D 11/30; H10K 50/844

(52) U.S. Cl. CPC C09D 11/30; H10K 50/844

(57) ABSTRACT

Disclosed is a photopolymerizable composition which improves optical properties as well as inkjet discharge properties. According to an aspect, provided is a photopolymerizable composition including: a first monomer having a first photocurable functional group; a second monomer having a second photocurable functional group; and an initiator, wherein the first and second monomers satisfy Equation 1.

### TECHNICAL FIELD

The present disclosure relates to a photopolymerizable composition, and more specifically, to a photopolymerizable composition, an optical member and an electronic device.

### BACKGROUND ART

In a light-transmitting optical film having a structured prism, a luminance increase rate changes by a refractive index of a resin forming the prism structure. A luminance increase rate generally increases as a refractive index of a resin forming a prism increases. Accordingly, regarding the light-transmitting optical film, research and development are being conducted in a direction of increasing a refractive index of a resin forming a prism structure.

When an existing general photopolymerizable composition is used as a monomer composition to form the resin and the optical film, sufficient surface curing often fails to occur due to the influence of oxygen in the air during the photocuring of the monomer composition. This leads to problems in that the resin and the optical film have increased haze, and reduced light transmittance such as UV transmittance, or reduced visibility.

In addition, insufficient surface curing degrades mechanical properties of the film, causing a significant decrease in high flexibility and bending reliability required for foldable devices. Accordingly, considering the above-described issues, conducting the curing process under an inert gas atmosphere such as nitrogen atmosphere has been considered, however, this may cause a significant increase in manufacturing costs.

Due to all the issues described above, development has not been made to a satisfactory level in terms of excellent optical properties, high flexibility and the like while exhibiting viscosity properties suitable for an ink jet process, and accordingly, there are continuous needs for the development of technology that enables formation of an optical film exhibiting excellent optical and mechanical properties.

### BRIEF DESCRIPTION OF THE INVENTION

### Technical Problem

The present disclosure is directed to providing a photopolymerizable composition that improves inkjet discharge properties.

The present disclosure is also directed to providing a photopolymerizable composition that increases a refractive index and transmittance of an optical member, and reduces haze thereof.

The present disclosure is also directed to providing an optical member in which the photopolymerizable composition is cured.

The present disclosure is also directed to providing an electronic device including the optical member.

Objects of the present disclosure are not limited to the above-mentioned objects, and other objects and advantages of the present disclosure not mentioned will be understood by the following description, and more clearly understood by embodiments of the present disclosure. In addition, it may be readily understood that objects and advantages of the present disclosure may be embodied by means described in the claims and combinations thereof.

### Technical Solution

According to a first aspect of the present disclosure to achieve the objects described above, there is provided a photopolymerizable composition comprising: a first monomer having a first photocurable functional group; a second monomer having a second photocurable functional group; and an initiator, wherein the first and second monomers satisfy the following Equation 1.

$$C = \vert A - B \vert \leq 8. mN / m \qquad [ Equation 1 ]$$

In Equation 1, C is an absolute value (mN/m) of a deviation of surface tension of the second monomer with respect to surface tension of the first monomer, A is surface tension (mN/m) of the first monomer at 25° C., and B is surface tension (mN/m) of the second monomer at 25° C.

According to a second aspect of the present disclosure, in the first aspect, the first monomer may have a liquid phase refractive index of 1.57 or more.

According to a third aspect of the present disclosure, in the first or second aspect, the first monomer may have surface tension of 41 mN/m or less.

According to a fourth aspect of the present disclosure, in any one of the first to third aspects, the first monomer may include at least one aromatic ring structure, or an aromatic compound including at least one heteroatom.

According to a fifth aspect of the present disclosure, in any one of the first to fourth aspects, the first monomer may include a structure represented by the following Chemical Formula 1.

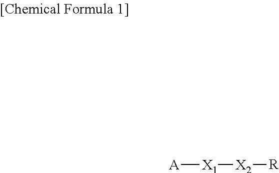

In Chemical Formula 1, A includes at least one structure among a substituted or unsubstituted aryl group; a substituted or unsubstituted aromatic heteroring; and a substituted or unsubstituted bicyclic structure, X₁ is a direct bond; or a divalent linking group having 1 to 20 carbon atoms including or not including at least one oxygen atom, X₂ is a direct bond; or a divalent linking group having 1 to 20 carbon atoms including or not including at least one oxygen atom, and R is the first photocurable functional group. Specifically, the substituted or unsubstituted bicyclic structure may be a bridged bicyclic structure. For example, in X₁ and X₂, the divalent linking group that does not include an oxygen atom may include at least one of an alkylene group, an alkenylene group and an alkynylene group.

According to a sixth aspect of the present disclosure, in the fifth aspect, in Chemical Formula 1, A may be a substituted or unsubstituted aryl group having 6 to 14 carbon atoms, X₁ may be a direct bond, and X₂ may be a divalent linking group having 1 to 10 carbon atoms including or not including at least one oxygen atom.

According to a seventh aspect of the present disclosure, in any one of the first to sixth aspects, the first monomer may include at least one selected from the group consisting of benzyl (meth)acrylate, phenoxyethyl (meth)acrylate, phenoxybenzyl (meth)acrylate, O-phenyl phenoxyethyl (meth)acrylate, biphenyl (meth)acrylate, biphenylethyl (meth)acrylate, and compounds represented by the following Chemical Formulae 2 to 9.

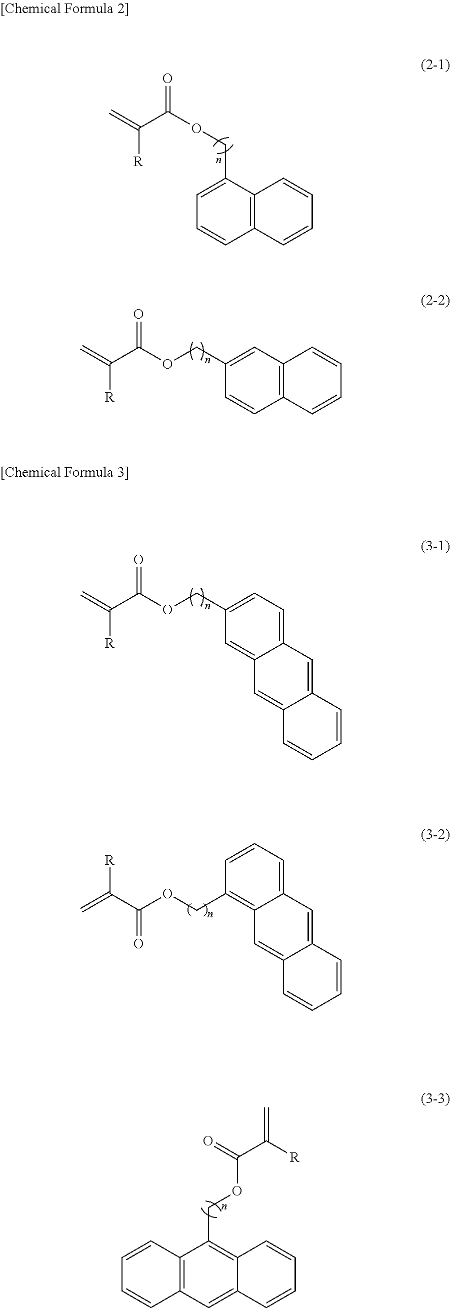

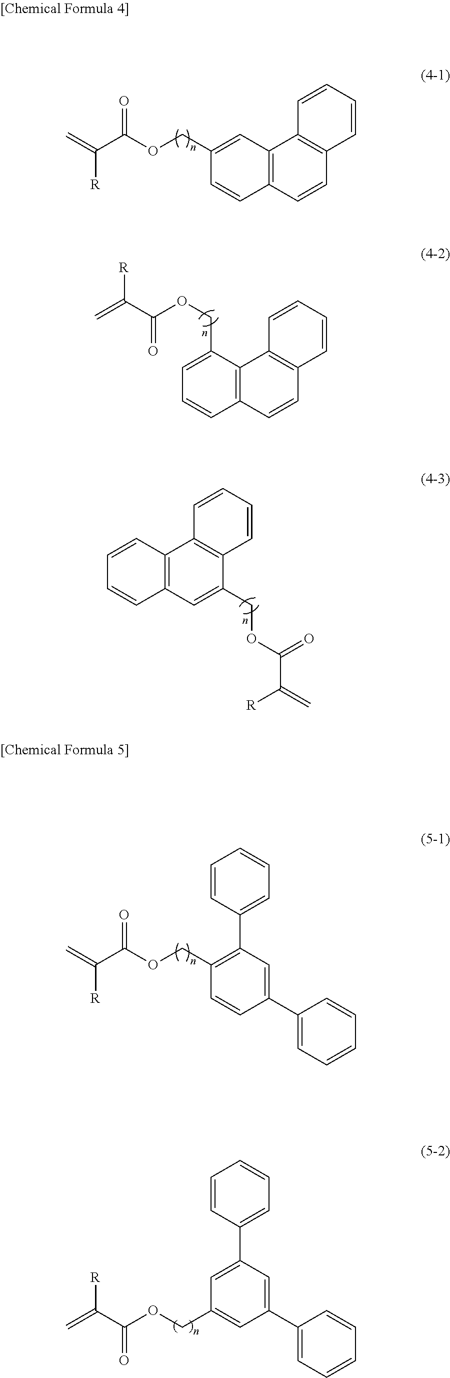

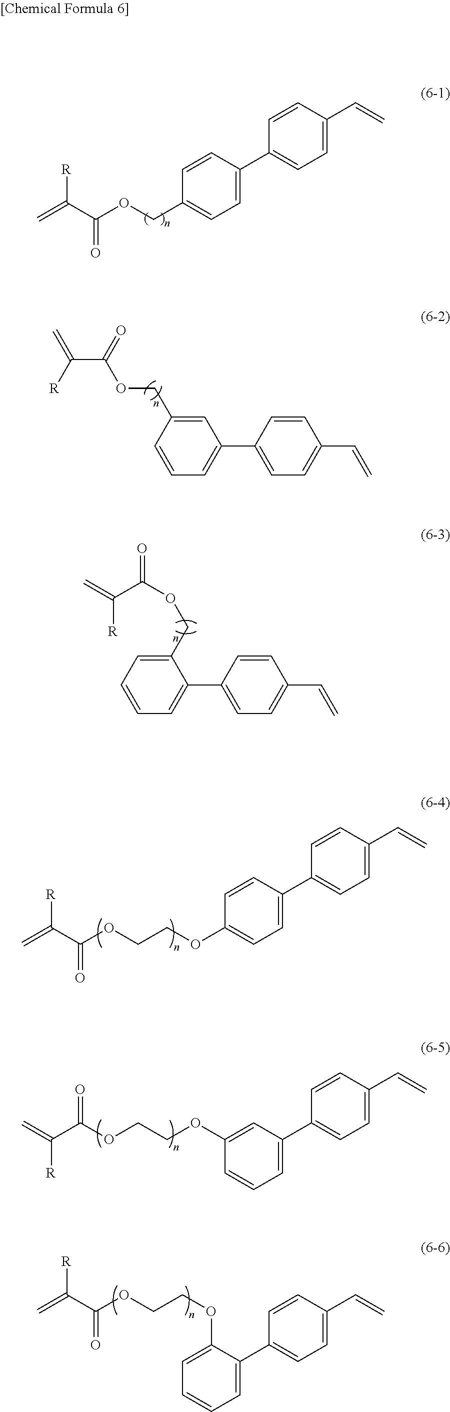

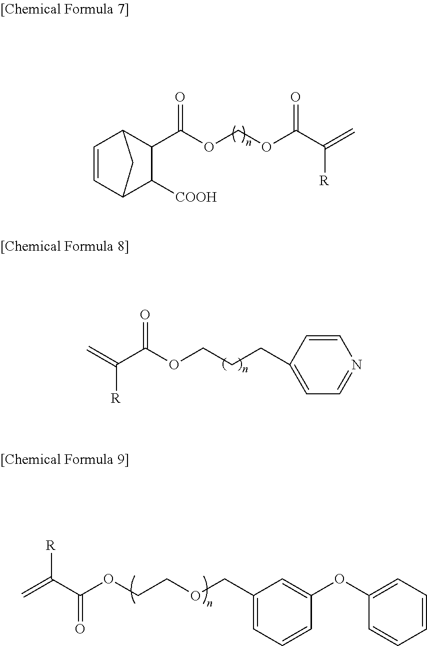

In Chemical Formulae 2 to 9, Rs are each independently a hydrogen atom or an alkyl group having 1 to 4 carbon atoms, and ns are each independently an integer of 0 to 10. For example, ns may be each independently 0, 1, 2, 3, 4, 5, 6, 7, 8, 9, or 10.

According to an eighth aspect of the present disclosure, in any one of the first to seventh aspects, the first monomer may have purity of 95% or higher.

According to a ninth aspect of the present disclosure, in any one of the first to eighth aspects, the first monomer may have purity of 98% or higher.

According to a tenth aspect of the present disclosure, in any one of the first to ninth aspects, a content of the first monomer may be from 30 parts by weight to 90 parts by weight with respect to 100 parts by weight of all the monomers including the first monomer and the second monomer.

According to an eleventh aspect of the present disclosure, in any one of the first to tenth aspects, the second monomer may include a structure represented by the following Chemical Formula 10.

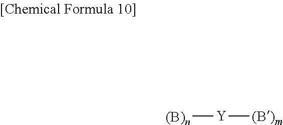

In Chemical Formula 10, B and B′ include the second photocurable functional groups that are the same as or different from each other, Y includes a substituted or unsubstituted hydrocarbon structure having 4 to 50 carbon atoms including or not including at least one oxygen atom, n and m are each independently an integer of 0 to 2, and n+m satisfies 1 or 2. Herein, Y may include, for example, a divalent linking group in which atoms linked to the second photocurable functional group are all oxygen atoms, and may specifically be —O—(CH₂)x-O—. For example, x may be 1 or more, and may specifically be 1, 2, 3, 4, 5, 6, 7, 8, or 9.

According to a twelfth aspect of the present disclosure, in the eleventh aspect, in Chemical Formula 10, Y may include, as an aliphatic or aromatic structure having 4 to 50 carbon atoms, an alkylene oxide group having 6 or more carbon atoms, an alkylene group having 6 or more carbon atoms, or an alkenylene group having 6 or more carbon atoms.

According to a thirteenth aspect of the present disclosure, in any one of the first to twelfth aspects, the second monomer may include at least one type selected from the group consisting of ethylene glycol di(meth)acrylate, propylene glycol di(meth)acrylate, neopentyl glycol di(meth)acrylate, diethylene glycol di(meth)acrylate, triethylene glycol di(meth)acrylate, tetraethylene glycol di(meth)acrylate, butanediol di(meth)acrylate, pentanediol di(meth)acrylate, 1,6-hexanediol di(meth)acrylate, 1,12-dodecanediol di(meth)acrylate, isostearyl acrylate, lauryl acrylate, 1,6-hexanediol ethoxylate di(meth)acrylate and a compound represented by the following Chemical Formula 11.

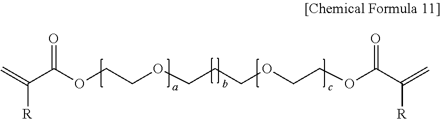

In Chemical Formula 11, Rs are each independently hydrogen or an alkyl group, and a, b and c are integers that satisfy a+b+c=1 to 20. For example, the alkyl group may be a linear or branched alkyl group having 1 to 5 carbon atoms.

According to a fourteenth aspect of the present disclosure, in the thirteenth aspect, in Chemical Formula 11, b is 0, and a and c may be an integer of 1 to 20.

According to a fifteenth aspect of the present disclosure, in any one of the first to fourteenth aspects, a content of the initiator may be from 0.5 parts by weight to 10 parts by weight with respect to 100 parts by weight of all the monomers including the first monomer and the second monomer.

According to a sixteenth aspect of the present disclosure, in any one of the first to fifteenth aspects, the initiator may include a radical initiator.

According to a seventeenth aspect of the present disclosure, in any one of the first to sixteenth aspects, there may be provided a photopolymerizable composition further comprising at least one type selected from the group consisting of a surfactant, an amine enhancer and a photosensitizer.

According to an eighteenth aspect of the present disclosure, in the seventeenth aspect, a content of the surfactant may be from 0.001 parts by weight to 20 parts by weight with respect to 100 parts by weight of all the monomers including the first monomer and the second monomer.

According to a nineteenth aspect of the present disclosure, in any one of the first to eighteenth aspects, there may be provided a photopolymerizable composition in a solvent-free form.

According to a twentieth aspect of the present disclosure, in any one of the first to nineteenth aspects, there may be provided a photopolymerizable composition having absolute viscosity measured at 25° C. of 5 cP to 40 cP.

According to a twenty first aspect of the present disclosure, there may be provided an optical member comprising a cured film in which the photopolymerizable composition according to any one of the first to twentieth aspects is cured.

According to a twenty second aspect of the present disclosure, in the twenty first aspect, the cured film may have haze of 3% or less, and average transmittance of 95% or more in a wavelength of 380 nm to 720 nm.

According to a twenty third aspect of the present disclosure, there is provided an electronic device comprising the optical member according to the twenty first or twenty second aspect.

The technical solutions do not list all the features of the present disclosure. Various features of the present disclosure and corresponding advantages and effects will be understood in more detail with reference to specific embodiments described below.

### Advantageous Effects

According to one aspect of the present disclosure, viscosity and surface tension of a photopolymerizable composition can be controlled to an appropriate level, and discharge properties of ink from a nozzle of an inkjet head can be improved.

According to another aspect of the present disclosure, refractive index and light transmittance of an optical member in which the photopolymerizable composition is cured are increased, and a haze value thereof is reduced, thereby improving optical properties.

Specific effects of the present disclosure in addition to the above-described effects will be described together while describing specific details for carrying out the disclosure hereinafter.

### BRIEF DESCRIPTION OF DRAWINGS

FIG. 1 shows results of inkjet discharge properties for photopolymerizable compositions according to an Example and a Comparative Example.

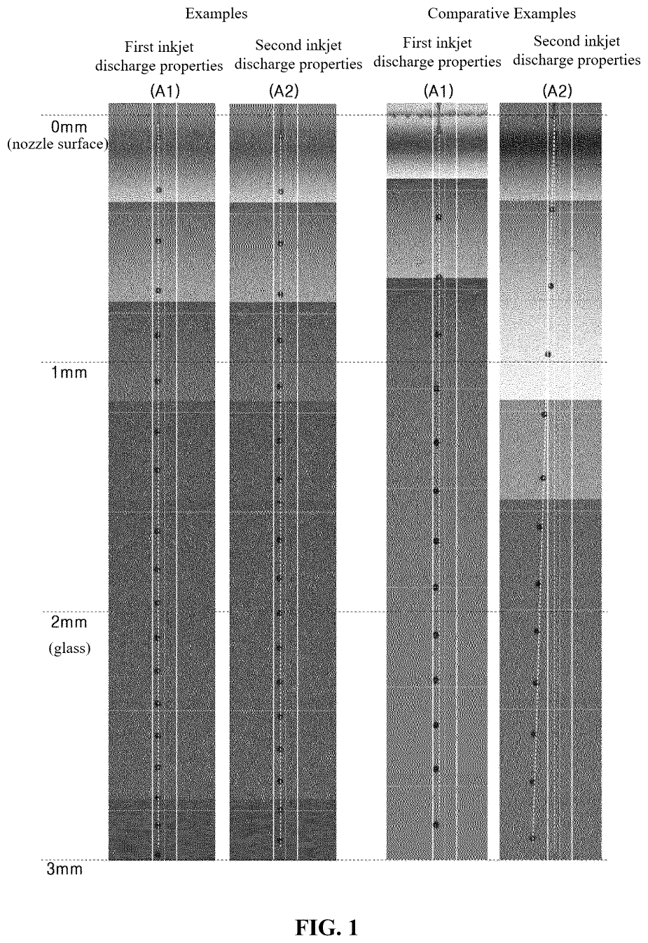

FIG. 2 shows results of inkjet droplet parameters for photopolymerizable compositions according to an example and a comparative example.

### BEST MODE

In the present specification, singular forms include plural forms, unless the context clearly indicates otherwise.

In the present specification, terms such as “include (comprise)” and/or “including (comprising)” specify the presence of mentioned shapes, steps, numbers, operations, members, elements and/or groups thereof, and do not exclude the presence or addition of one or more other shapes, steps, numbers, operations, members, elements and/or groups thereof.

In the present specification, “at least one of a, b and c” may include a, b or c alone, or may include a combination of at least two selected from the group consisting of a, b and c.

When multiple embodiments are described in the present specification, each embodiment may be combined unless specifically stated to the contrary. Herein, effects of the present disclosure may be defined to include not only the effects obtained from each embodiment, but also the effects occurring as respective embodiments are organically combined. For example, even when embodiments 1 and 2 are each independently described in the present specification, embodiments 1 and 2 may be organically combined with each other unless the context clearly indicates otherwise, and effects of the present disclosure may include the effects occurring as embodiments 1 and 2 are combined.

In the present specification, a numerical range indicated by using a term “to” represents a numerical range including values described before and after the term respectively as a lower limit value and an upper limit value. When numerical values as upper and lower limits of any numerical range are each disclosed in multiple numbers, the numerical range disclosed in the present specification may be understood as any numerical range having any one of the multiple lower limit values and any one of the multiple upper limit values as a lower limit value and an upper limit value, respectively. For example, when a to b, or c to d is described in the present specification, it may be understood that a or more and b or less, a or more and d or less, c or more and d or less, or c or more and b or less is described.

In the present specification, a “layer” or film may include a case in which, when observing an area in which the corresponding layer or film is present, the layer or film is formed on only a portion of the corresponding area in addition to the case in which the layer or film is formed over the entire corresponding area. For example, the surface of the layer or film may be defined to have a flat shape, a non-flat shape and a combination thereof, or a continuous shape, a discontinuous shape and a combination thereof. For example, when another member is formed as a layer or film directly on one member, the coverage of the surface of one member by another member may be defined as 1% or more, 5% or more, 10% or more, 20% or more, 30% or more, 40% or more, 50% or more, 60% or more, 70% or more, 80% or more, 85% or more, 90% or more, 95% or more or 99% or more. For example, when a plurality of particles form a clustered structure, it may be defined as a “layer” or “film”.

In the present specification, a “weight average molecular weight” or “number average molecular weight” is a standard polystyrene-converted molecular weight and may be analyzed through a GPC (gel permeation chromatography) device. For example, in the GPC analysis method, the developing solvent may be tetrahydrofuran (THF), the column may be PL Olexis manufactured by Polymer Laboratories, the sample concentration may be 5 mg/mL, the amount of sample injection may be 100 μl, the flow rate may be 1 mL/min, the detector may be an Agilent High Temperature RI detector, and the column temperature may be set to 40° C.

In the present specification, unless defined otherwise below, “substituted” is defined as at least one hydrogen atom being replaced with any one selected from the group consisting of a halogen atom, a hydroxyl group, a carboxyl group, a nitro group, an amine group, a sulfide group, a thiol group, an alkoxy group, an acetoxy group, a nitrile group, an aldehyde group, an ether group, an ester group, an acetal group, a ketone group, a C₁ to C₃₀ alkyl group, a C₂ to C₃₀ alkenyl group, a C₂ to C₃₀ alkynyl group, a C₁ to C₄₀ alkylsilyl group, a C₂ to C₄₀ arylsilyl group, a C₃ to C₃₀ cycloalkyl group, a C₃ to C₃₀ allyl group, a C₆ to C₃₀ aryl group, a heterocyclic group (for example: a C₂ to C₃₀ heterocycloalkyl group, a C₃ to C₃₀ heteroaryl group), derivatives thereof and combinations thereof. Herein, each of the substituents may bond to each other when adjacent to each other to form a substituted or unsubstituted fused ring or spiro structure.

In the present specification, the “fused ring” means a ring in which two or more rings bind by sharing two or more atoms, and examples thereof may include a fused aliphatic ring, a fused aromatic ring, a fused heteroaliphatic ring, a fused heteroaromatic ring or a combination thereof.

In the present specification, the “spiro structure” has a spiro union, and the spiro union means a union formed by two rings sharing only one atom.

In the present specification, “(meth)acrylate” may be defined to include an acrylate or methacrylate group.

According to one aspect of the present disclosure, there is provided a photopolymerizable composition including: a first monomer having a first photocurable functional group; a second monomer having a second photocurable functional group; and an initiator, wherein the first and second monomers satisfy the following Equation 1.

$$C = \vert A - B \vert \leq 8. mN / m \qquad [ Equation 1 ]$$

In Equation 1, C is an absolute value (mN/m) of a deviation of surface tension of the second monomer with respect to surface tension of the first monomer, A is surface tension (mN/m) of the first monomer at 25° C., and B is surface tension (mN/m) of the second monomer at 25° C. According to one aspect of the present disclosure, as an absolute value (mN/m) of a deviation of surface tension of the second monomer with respect to surface tension of the first monomer satisfies the range of 8.0 mN/m or less, viscosity and surface tension of the photopolymerizable composition are controlled to an appropriate level, allowing ink to be favorably discharged from a nozzle of an inkjet head without clogging. According to another aspect of the present disclosure, as an absolute value (mN/m) of a deviation of surface tension of the second monomer with respect to surface tension of the first monomer satisfies the range of 8.0 mN/m or less, an optical member having increased refractive index, reduced haze value and high light transmittance may be obtained.

Hereinafter, constitutions of the present disclosure will be described in more detail.

### 1. Photopolymerizable Composition

### First Monomer

The photopolymerizable composition according to the present disclosure includes a first monomer having a first photocurable functional group capable of increasing a refractive index of an optical member.

Specifically, the first photocurable functional group may include a reactive functional group capable of a photopolymerization reaction in the presence of an initiator. For example, the first photocurable functional group may include any one selected from the group consisting of a (meth)acryl group, a carbon-carbon unsaturated bond and combinations thereof. Specifically, the carbon-carbon unsaturated bond may be a carbon-carbon double bond or a carbon-carbon triple bond. Herein, at least one carbon-carbon unsaturated bond may be included in the first monomer. Herein, the (meth)acryl group may be an unsaturated carbonyl group including a carbon-carbon double bond formed with alpha and beta carbons; or a group in which a hydrogen atom or an alkyl group having one or more carbon atoms bond to the alpha carbon [alkyl (meth)acryl group].

According to one embodiment of the present disclosure, the first monomer may have a liquid phase refractive index of 1.57, specifically 1.57 to 1.65, and more specifically 1.58 to 1.63. As the liquid phase refractive index of the first monomer satisfies the above-mentioned numerical range, the refractive index of a cured film by UV irradiation or the like may be increased.

According to one embodiment of the present disclosure, the first monomer may have surface tension of 43 mN/m or less, 42.4 mN/m or less, 41 mN/m or less, 40 mN/m or less, 39 mN/m or less, 38.9 N/m or less, 38 mN/m or less or 37.8 mN/m or less, and specifically, 37 mN/m or more and any one of the above-mentioned plurality of numbers or less. Specifically, as the surface tension of the first monomer satisfies the above-mentioned numerical range, the effect of discharge properties becoming superior may be further achieved when the photopolymerizable composition is used as ink in an inkjet printer, and the discharged photopolymerizable composition may be sufficiently cured. According to one embodiment, the surface tension of the first monomer may be measured by a Du Nouy Ring or Wilhelmy Plate method at 25° C. using a surface tensiometer (device name: K20 of KRUSS Scientific).

According to one embodiment of the present disclosure, the first monomer may include at least one aromatic ring structure, or an aromatic compound including at least one heteroatom. Specifically, the first monomer includes at least one aromatic ring structure or an aromatic compound including at least one heteroatom, thereby improving optical properties of an optical member and further improving discharge properties of ink by controlling surface tension and viscosity of the photopolymerizable composition to an appropriate level.

According to one embodiment of the present disclosure, the first monomer may include a structure represented by the following Chemical Formula 1.

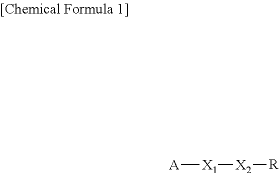

In Chemical Formula 1, A includes at least one structure among a substituted or unsubstituted aryl group; a substituted or unsubstituted aromatic heteroring; and a substituted or unsubstituted bridged bicyclic structure, X₁ is a direct bond; or a divalent linking group having 1 to 20 carbon atoms including or not including at least one oxygen atom, X₂ is a direct bond; or a divalent linking group having 1 to 20 carbon atoms including or not including at least one oxygen atom, and R is the first photocurable functional group.

For example, an aryl group in A may include one or more, two or more, or three or more benzene rings. Herein, the benzene ring may be a substituted or unsubstituted benzene ring. For example, the aromatic heteroring may be an aromatic ring including at least one heteroatom, and specifically, an aromatic ring including any one selected from the group consisting of a nitrogen atom, an oxygen atom, a sulfur atom and combinations thereof. For example, the bridged bicyclic structure may have two rings sharing two carbon atoms, and at least one hydrogen atom bonding to the parent unit of the bridged bicyclic structure may be substituted with a functional group including a carboxyl group and the like.

In some embodiments, the bridged bicyclic structure may include a fused aromatic ring, and may specifically be a naphthalene group, an anthracene group, a phenanthrene group, a perylene group or a tetracene group.

For example, the divalent linking group having 1 to 20 carbon atoms including at least one oxygen atom in X₁ may include at least one of an ester group (—COO— or —OOC—), an ether group (—O—) and a ketone group (—CO—). Specifically, the divalent linking group may include at least one of aliphatic structure and aromatic structure having 1 to 20 carbon atoms. More specifically, the aliphatic structure may include any one selected from the group consisting of an aliphatic chain-type structure, an aliphatic ring-type structure and combinations thereof satisfying the above-described carbon number range. In addition, the aromatic structure may include any one selected from the group consisting of an aryl group, a heteroaryl group and combinations thereof satisfying the above-described carbon number range.

For example, the divalent linking group having 1 to 20 carbon atoms including at least one oxygen atom in X₂ may include at least one of an ester group (—COO— or —OOC—), an ether group (—O—) and a ketone group (—CO—). Specifically, the divalent linking group may include at least one of aliphatic structure and aromatic structure having 1 to 20 carbon atoms. More specifically, the aliphatic structure may include any one selected from the group consisting of an aliphatic chain-type structure, an aliphatic ring-type structure and combinations thereof satisfying the above-described carbon number range. In addition, the aromatic structure may include any one selected from the group consisting of an aryl group, a heteroaryl group and combinations thereof satisfying the above-described carbon number range.

According to one embodiment of the present disclosure, in Chemical Formula 1, A is a substituted or unsubstituted aryl group having 6 to 14 carbon atoms, X₁ is a direct bond, and X₂ may be a divalent linking group having 1 to 10 carbon atoms including or not including at least one oxygen atom, and may specifically be a divalent linking group having 1 to 10 carbon atoms including at least one oxygen atom. Specifically, as the following conditions are satisfied: in Chemical Formula 1, A is a substituted or unsubstituted aryl group having 6 to 14 carbon atoms, X₁ is a direct bond, and X₂ is a divalent linking group having 1 to 10 carbon atoms including at least one oxygen atom, optical properties (example: high refractive index and low haze) of an optical member are improved, and at the same time, inkjet discharge properties may be further improved by controlling surface tension and viscosity of the photopolymerizable composition to an appropriate level.

For example, the first monomer may include at least one selected from the group consisting of benzyl (meth)acrylate, phenoxyethyl (meth)acrylate, phenoxybenzyl (meth)acrylate, O-phenyl phenoxyethyl (meth)acrylate, biphenyl (meth)acrylate, biphenylethyl (meth)acrylate, and compounds represented by the following Chemical Formulae 2 to 9.

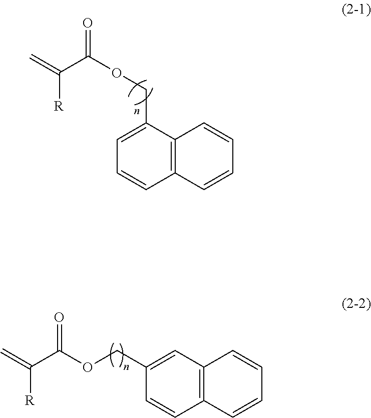

The compound represented by Chemical Formula 2 may include at least one selected from the group consisting of compounds represented by Chemical Formulae 2-1 and 2-2.

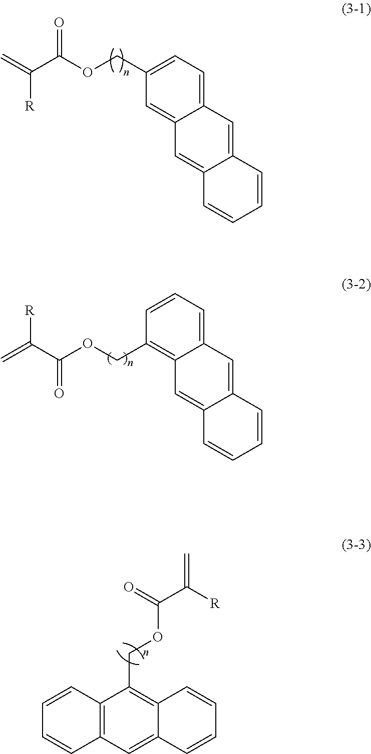

The compound represented by Chemical Formula 3 may include at least one selected from the group consisting of compounds represented by Chemical Formulae 3-1 to 3-3.

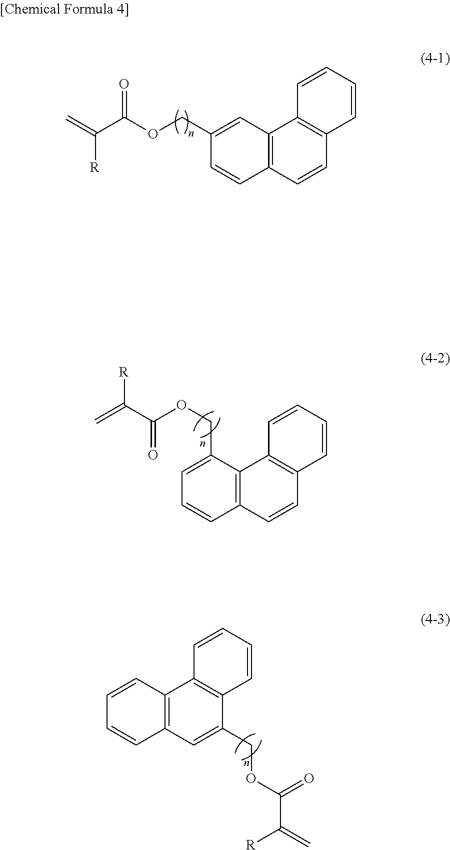

The compound represented by Chemical Formula 4 may include at least one selected from the group consisting of compounds represented by Chemical Formulae 4-1 to 4-3.

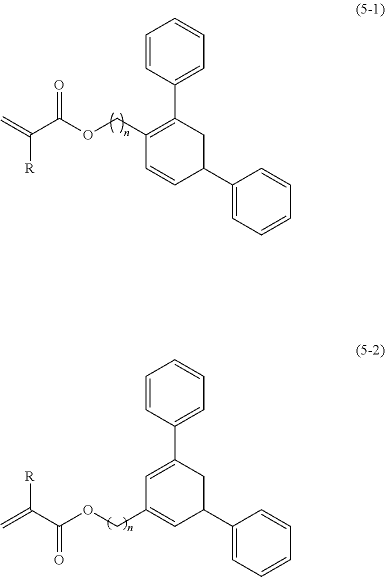

The compound represented by Chemical Formula 5 may include at least one selected from the group consisting of compounds represented by Chemical Formulae 5-1 and 5-2.

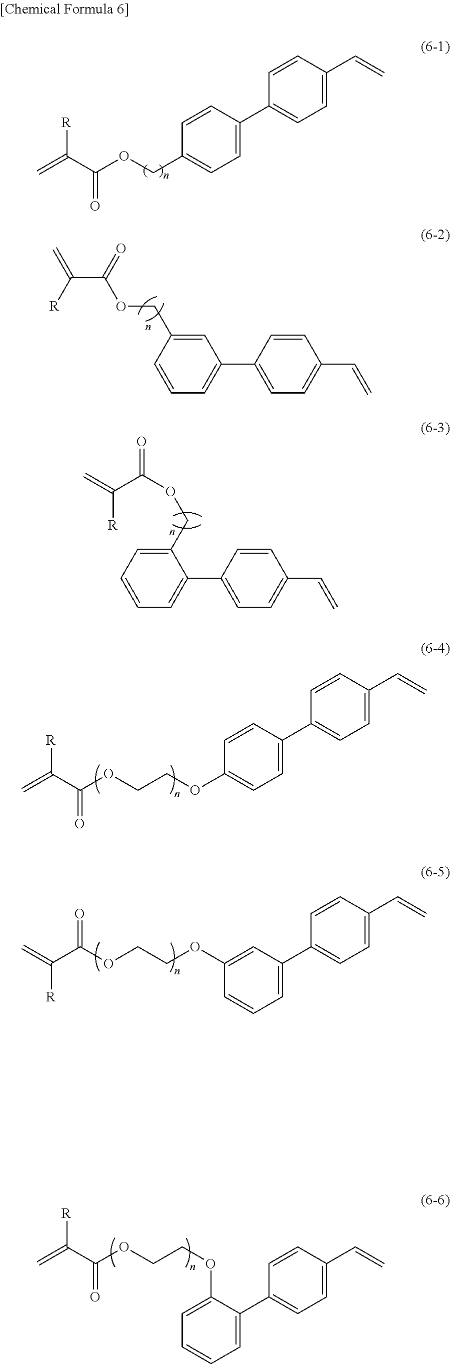

The compound represented by Chemical Formula 6 may include at least one selected from the group consisting of compounds represented by Chemical Formulae 6-1 to 6-6.

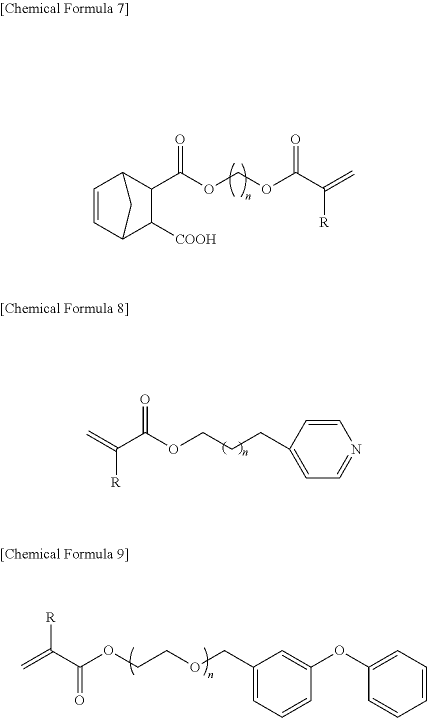

In Chemical Formulae 2 to 9, Rs are each independently a hydrogen atom or an alkyl group having 1 to 4 carbon atoms, and ns are each independently an integer of 0 to 10. For example, in Chemical Formulae 2 to 9, ns may be each independently 0, 1, 2, 3, 4, 5, 6, 7, 8, 9, or 10.

According to one embodiment of the present disclosure, the first monomer may have purity of 94% or higher, 95% or higher, 96% or higher, specifically 98% or higher, and more specifically 98.01% to 99.99%. Specifically, as the purity of the first monomer satisfies the above-mentioned numerical range, inkjet discharge properties and inkjet droplet parameter properties may be improved to be more superior. More specifically, even when the purity of the first monomer satisfies the above-mentioned range, when an absolute value (mN/m) of a deviation of surface tension of the second monomer with respect to surface tension of the first monomer is more than 8.0 mN/m, there may be a problem of discharge properties of the photopolymerizable composition being not sufficiently improved. According to one embodiment, the purity of the first monomer may be measured using liquid chromatography or gas chromatography.

According to one embodiment of the present disclosure, the content of the first monomer may be from 30 parts by weight to 90 parts by weight, 40 parts by weight to 80 parts by weight, 45 parts by weight to 70 parts by weight, 50 parts by weight to 60 parts by weight, or 55 parts by weight to 65 parts by weight with respect to 100 parts by weight of all the monomers including the first monomer and the second monomer. As the content of the first monomer satisfies the above-mentioned numerical range, optical properties (example: high refractive index and low haze) of an optical member are improved, and at the same time, inkjet discharge properties may be further improved by controlling surface tension and viscosity of the photopolymerizable composition to an appropriate level.

### Second Monomer

The photopolymerizable composition according to the present disclosure includes a second monomer having a second photocurable functional group in order to lower viscosity of the photopolymerizable composition and adjust curing rate and curing degree of the photopolymerizable composition. Specifically, the second photocurable functional group may be the same as or different from the first photocurable functional group described above.

Specifically, the second monomer may include a structure represented by the following Chemical Formula 10, and more specifically, may include a compound represented by the following Chemical Formula 10.

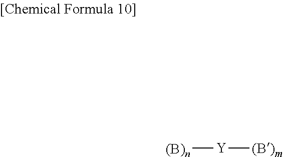

In Chemical Formula 10, B and B′ include the second photocurable functional groups that are the same as or different from each other, Y includes a substituted or unsubstituted hydrocarbon structure having 4 to 50 carbon atoms including or not including at least one oxygen atom, n and m are an integer of 0 to 2, and n+m satisfies 1 or 2.

For example, when Y includes a substituted or unsubstituted hydrocarbon structure having 4 to 50 carbon atoms including at least one oxygen atom in Chemical Formula 10, the corresponding Y may be a divalent linking group (—O-Rm-O—) including an oxygen atom at one end (—O-Rm- or -Rm-O—) or both ends. Herein, Rm may be a linear or branched alkylene group having 4 to 50 carbon atoms including or not including at least one ether group.

According to one embodiment of the present disclosure, Y may include an alkylene oxide group having 6 or more carbon atoms, an alkylene group having 6 or more carbon atoms or an alkenylene group having 6 or more carbon atoms as the aliphatic or aromatic structure having 4 to 50 carbon atoms in Chemical Formula 10. According to one embodiment of the present disclosure, as the second monomer includes the structure represented by Chemical Formula 10, an absolute value (mN/m) of a deviation of surface tension of the second monomer with respect to surface tension of the first monomer may satisfy 8.0 mN/m or less. Accordingly, viscosity and surface tension of the photopolymerizable composition are controlled to an appropriate level, allowing ink to be favorably discharged from a nozzle of an inkjet head. According to another aspect of the present disclosure, an optical member having increased refractive index, reduced haze value and high light transmittance may be obtained.

For example, the second monomer may include at least one type selected from the group consisting of ethylene glycol di(meth)acrylate, propylene glycol di(meth)acrylate, neopentyl glycol di(meth)acrylate, diethylene glycol di(meth)acrylate, triethylene glycol di(meth)acrylate, tetraethylene glycol di(meth)acrylate, butanediol di(meth)acrylate, pentanediol di(meth)acrylate, 1,6-hexanediol di(meth)acrylate, 1,12-dodecanediol di(meth)acrylate, isostearyl acrylate, lauryl acrylate, 1,6-hexanediol ethoxylate di(meth)acrylate and a compound represented by the following Chemical Formula 11.

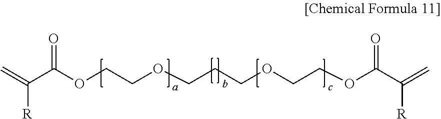

In Chemical Formula 11, Rs are each independently hydrogen or an alkyl group, and a, b and c are integers that satisfy a+b+c=1 to 20. More specifically, b is 0, and a and c may be an integer of 1 to 20 in Chemical Formula 11. For example, the alkyl group may be a linear or branched alkyl group having 1 to 5 carbon atoms.

According to one embodiment of the present disclosure, the content of the second monomer may be from 10 parts by weight to 70 parts by weight, 20 parts by weight to 60 parts by weight, 30 parts by weight to 55 parts by weight or 40 parts by weight to 50 parts by weight with respect to 100 parts by weight of all the monomers including the first monomer and the second monomer. As the content of the second monomer satisfies the above-mentioned numerical range, viscosity and surface tension of the photopolymerizable composition are controlled to an appropriate level, and discharge properties may become superior when the photopolymerizable composition is used as ink for inkjet print.

According to one embodiment of the present disclosure, the second monomer may have surface tension measured at 25° C. of 30 mN/m or more, specifically 31 mN/m to 40 mN/m, and more specifically 32.8 mN/m to 39.3 mN/m. As the surface tension of the second monomer satisfies the above-mentioned numerical range, viscosity and surface tension of the photopolymerizable composition are controlled to an appropriate level, and discharge properties may become superior when the photopolymerizable composition is used as ink for inkjet print.

### Relationship Between First Monomer and Second Monomer

According to one aspect of the present disclosure, there is provided a photopolymerizable composition including: a first monomer having a first photocurable functional group; a second monomer having a second photocurable functional group; and an initiator, wherein the first and second monomers satisfy the following Equation 1.

$$C = \vert A - B \vert \leq 8. mN / m \qquad [ Equation 1 ]$$

In Equation 1, C is an absolute value (mN/m) of a deviation of surface tension of the second monomer with respect to surface tension of the first monomer, A is surface tension (mN/m) of the first monomer at 25° C., and B is surface tension (mN/m) of the second monomer at 25° C. According to one aspect of the present disclosure, as an absolute value (mN/m) of a deviation of surface tension of the second monomer with respect to surface tension of the first monomer satisfies the range of 8.0 mN/m or less, viscosity and surface tension of the photopolymerizable composition are controlled to an appropriate level, allowing ink to be favorably discharged from a nozzle of an inkjet head. According to another aspect of the present disclosure, as an absolute value (mN/m) of a deviation of surface tension of the second monomer with respect to surface tension of the first monomer satisfies the range of 8.0 mN/m or less, an optical member having increased refractive index, reduced haze value and high light transmittance may be obtained.

Specifically, in Equation 1, C may satisfy 5.0 mN/m or less or 2.5 mN/m or less. According to one embodiment of the present disclosure, as C is satisfied in Equation 1, viscosity and surface tension of the photopolymerizable composition are controlled, and discharge properties of ink from a nozzle of an inkjet head may be further improved.

### Initiator

The photopolymerizable composition according to the present disclosure includes an initiator to initiate and accelerate the photocuring reaction of the first monomer and the second monomer described above.

The content of the initiator according to the present disclosure may be from 0.5 parts by weight to 10 parts by weight, 2 parts by weight to 10 parts by weight, 3 parts by weight to 9 parts by weight, 4 parts by weight to 8 parts by weight, or 5 parts by weight to 7 parts by weight with respect to 100 parts by weight of all the monomers including the first monomer and the second monomer. When the content of the initiator satisfies the above-mentioned numerical range, the photocuring reaction proceeds sufficiently, and transmittance of a cured film in which the photopolymerizable composition is cured may sufficiently increase at the same time.

For example, the initiator may be a radical initiator inducing the photopolymerization reaction by a radical mechanism.

According to another embodiment of the present disclosure, the initiator and the first monomer may have a weight ratio (initiator:first monomer) of 1:5 to 1:120. Specifically, as the weight ratio between the initiator and the first monomer (initiator:first monomer) satisfies the above-mentioned numerical range, the photocuring reaction proceed sufficiently, and transmittance of a cured film in which the photopolymerizable composition is cured may sufficiently increase at the same time.

According to another embodiment of the present disclosure, the initiator and the second monomer may have a weight ratio (initiator:second monomer) of 1:3 to 1:90. Specifically, as the weight ratio between the initiator and the second monomer (initiator:second monomer) satisfies the above-mentioned numerical range, the photocuring reaction proceed sufficiently, and transmittance of a cured film in which the photopolymerizable composition is cured may sufficiently increase at the same time.

According to one embodiment, the initiator may include at least one type selected from the group consisting of benzoin-based, benzophenone-based, imidazole-based, phenylglyoxylate-based, xanthone-based, oxime ester-based, acetophenone-based, hydroxyketone-based, aminoketone-based, benzyldimethyl-based, monoacylphosphine-based, bisacylphosphine-based, metallocene-based, iodonium salt or phosphine oxide-based compounds including 2,4-bistrichloromethyl-6-p-methoxystyryl-s-triazine, 2-p-methoxystyryl-4,6-bistrichloromethyl-s-triazine, 2,4-trichloromethyl-6-triazine, 2,4,-trichloromethyl-4-methylnaphthyl-6-triazine, 2-(o-chlorophenyl)-4,5-diphenyl imidazole dimer, 2-(o-chlorophenyl)-4,5-di(m-methoxyphenyl) imidazole dimer, 2-(o-fluorophenyl)-4,5-diphenyl imidazole dimer, 2-(-o-methoxyphenyl)-4,5-diphenyl imidazole dimer, 2,4,-di(p-methoxyphenyl)-5-phenyl imidazole dimer, 2-(2,4-dimethoxyphenyl)-4,5-diphenyl imidazole dimer, 2-(p-methylmercaptophenyl)-4,5-diphenyl imidazole dimer, [1-[9-ethyl-6-(2-methylbenzoyl)-9H-carbazoyl-3-yl]-1-(O-acetyloxime), benzophenone, p-(diethylamino)benzophenone, 2,2-dichloro-4-phenoxyacetophenone, 2,2-diethoxyacetophenone, 2-dodecylthioxanthone, 2,4-dimethylthioxanthone, 2,4-diethylthioxanthone, 2,2,-bis-2-chlorophenyl, 4,5,4,5-tetraphenyl-2-1,2-biimidazole, (E)-2-(acetoxyimino)-1-(9,9-diethyl-9H-fluoren-2-yl) butanone, (E)-1-(9,9-dibutyl)-7-nitro-9H-fluoren-2-yl]-ethanone O-acetyl oxime, (Z)-2-(acetoxyimino)-1-(9,9-diethyl-9H-fluoren-2-yl) propanone, 2,4,6-trimethylbenzoyl-diphenyl-phosphine oxide, ethyl(2,4,6-trimethylbenzoyl)phenylphosphinate, IRGACURE 184, IRGACURE 500, IRGACURE 2959, DAROCUR 1173, IRFACURE 754, DAROCUR MBF, IRFACURE 651, IRFACURE 369, IRFACURE 907, IRFACURE 1300, DAROCUR TPO, Omnirad TPO-L, IRFACURE 819, IRFACURE 819DW, IRFACURE 2100, IRGACURE 784, IRGACURE 250, OXE-01, OXE-02, OXE-03, OXE-04, N-1919, NCI-831, NCI-930 and the like.

### Additive

The photopolymerizable composition according to the present disclosure may further include at least one type selected from the group consisting of a surfactant, an amine enhancer and a photosensitizer, and may specifically include a surfactant.

The surfactant according to the present disclosure may improve thickness uniformity and surface smoothness of a cured film in which the photopolymerizable composition is cured.

Specifically, the content of the surfactant may be from 0.001 parts by weight to 20 parts by weight, 0.001 parts by weight to 5 parts by weight, 0.01 parts by weight to 0.05 parts by weight, or 0.03 parts by weight to 0.05 parts by weight with respect to 100 parts by weight of all the monomers including the first monomer and the second monomer. As the content of the surfactant satisfies the above-mentioned numerical range, thickness uniformity and surface smoothness of the cured film may be improved, and at the same time, inkjet discharge properties may be further improved by effectively preventing bubble formation inside the film.

According to one embodiment, the surfactant may include at least one type selected from the group consisting of fluorine-based and silicone-based surfactants such as BM-1000 and BM-1100 (BM CHEMIE), Megafac F-142D, F-172, F-173, F-183, F-470, F-471, F-475, F-482 and F-489 (Dainippon Ink & Coatings, Inc.), Fluorad FC-135, FC-170C, FC-430 and FC-431 (Sumitomo 3M Ltd.), F-top EF301, EF303 and EF352 (New Akita Chemical Company), Surflon S-112, S-131, S-141, S-145, S-382, SC-101, SC-102, SC-103, SC-104, SC-105 and SC-106 (Asahi Glass Co, Ltd.), SH-28 PA, SH-190, SH-193, SZ-6032, SF-6032, SF-8428, DC-57 and DC-190 (Toray Silicone), DC3PA, DC7PA, SH11PA, SH21PA, SH8400, FZ-2100, FZ-2110, FZ-2122, FZ-2222 and FZ-2233 (Dow Corning Toray Silicone), TSF-4440, TSF-4300, TSF-4445, TSF-4446, TSF-4460 and TSF-4452 (GD Toshiba Silicone), BYK-333 (BYK), ESS-110, ESS-210, ESS-310 and CoatOSil Series (Momentive Performance Materials Inc.); nonionic surfactants such as polyethylene oxyalkyl ethers such as polyoxyethylene lauryl ether, polyoxyethylene stearyl ether and polyoxyethylene oleyl ether, polyoxyethylene aryl ethers such as polyethylene octylphenyl ether and polyoxyethylene nonylphenyl ether, and polyoxyethylene dialkyl esters such as polyethylene dilaurate and polyoxyethylene distearate; organosiloxane polymer KP341 (Shin-Etsu Chemical Co., Ltd.), (meth)acrylic acid-based copolymers such as Nos. 57 and 95 (Kyoeisha Chemical Co., Ltd.), and the like.

The amine enhancer according to the present disclosure may increase surface hardness of the cured film while reducing haze of an optical member. Specifically, the amine group of the amine enhancer may accelerate the reaction of the initiator by capturing oxygen radicals and the like in the air. In addition, when the amine enhancer is provided with a photocurable functional group, it may also form a crosslinking bond with the first and second monomers described above. The amine enhancer is not particularly limited, and specific examples thereof may include ethyl dimethylamino benzoate, butoxyethyl dimethylamino benzoate, diethylaminoethyl (meth)acrylate and the like.

The photosensitizer according to the present disclosure may accelerate the photopolymerization reaction. For example, the photosensitizer may include at least one type selected from the group consisting of isopropyl thioxanthone, pyrene, perylene, triphenylene, anthracene, 9,10-dibutoxyanthracene, 9,10-diethoxyanthracene, 3,7-dimethoxyanthracene, and 9,10-dipropyloxyanthracene.

### Properties of Photopolymerizable Composition

In some embodiments of the present disclosure, the photopolymerizable composition may be in a solvent-free form that does not include a solvent. Specifically, the photopolymerizable composition may have absolute viscosity measured at 25° C. of 5 cP to 40 cP. As the absolute viscosity of the photopolymerizable composition satisfies the above-mentioned numerical range, inkjet discharge properties may be improved. For example, absolute viscosity of the photopolymerizable composition may be measured at 25° C. using a viscometer (device name: Viscometer of AMETEK Brookfield).

In some embodiments of the present disclosure, the photopolymerizable composition may have an inkjet droplet parameter (IDP) of 95% or more, 96% or more, 97% or more, 98% or more, or 99% or more. Herein, a method for measuring the inkjet droplet parameter may include: discharging 500 droplets of the first photopolymerizable composition sample onto a substrate through an inkjet device, and then setting an average distance between the formed droplets to B1 (unit: μm); setting an average distance between droplets of the separate second photopolymerizable composition sample, which has been allowed to stand by in an inkjet head for a long time of 3 days at a temperature of 40° C. or less, to B2 (unit: μm) in the same manner as the first photopolymerizable composition sample; and calculating an inkjet droplet parameter in accordance with the following Equation 2. Specifically, when the inkjet droplet parameter (IDP) of the photopolymerizable composition satisfies the above-mentioned numerical range, ink may be favorably discharged from the inkjet head without clogging. In addition, the inkjet droplet parameter of the photopolymerizable composition may be a factor affecting at least one of a refractive index, a haze value and light transmittance of the cured film.

$$IDP \to \{ \frac{B 1 - B 2}{B 2} \} \times 100 \qquad [ Equation 2 ]$$

According to another aspect of the present disclosure, there may be provided an optical member including a cured film in which the photopolymerizable composition is cured. Specifically, the cured film may have haze of 3% or less, 2% or less or less than 1.0%, and average transmittance of 95% or more, 96% or more or 97% or more in a wavelength of 380 nm to 720 nm.

For example, the optical member may be an optical film or a patterned pattern film.

According to another embodiment of the present disclosure, the cured film may be disposed on a substrate. For example, the substrate may be a silicon wafer or the like.

According to another embodiment, the optical member may be manufactured by a method of coating the photopolymerizable composition of one embodiment described above on the substrate using a Mayer bar, an applicator for coating, an ink jet device or the like, and photocuring the result through exposure using an LED lamp, a metal halide lamp or the like. Herein, the photopolymerizable composition may be coated in a single layer form and then photocured to be formed into an optical member having a general optical film form, however, as necessary, the photopolymerizable composition may be coated to have a certain pattern form using the inkjet device, and then photocured. In this case, the optical member may have, for example, a form of a pattern film in which a cured film patterned in a polyhedral form such as a prism structure is formed on a substrate.

The optical member such as an optical film or a pattern film described above may have a general thickness depending on the type of the optical member or the structure of the electronic device to which it is applied, and for example, may have a thickness adjusted in the range of 0.01 μm to 1000 μm.

In some embodiments, the cured film may have a refractive index, which is measured at a wavelength of 450 nm using an ellipsometer, of 1.60 or more.

### 3. Electronic Device

According to another aspect of the present disclosure, there is provided an electronic device including the optical member.

According to another aspect of the present disclosure, there is provided an electronic device including a cured film in which the photopolymerizable composition of some embodiments is cured. For example, the electronic device may be an organic light emitting device, a solar cell device, an electrochromic material, an electrophoretic device, an organic thin film transistor, or an organic memory device.

According to another embodiment of the present disclosure, the cured film in which the photopolymerizable composition is cured may be disposed on the front surface of the electronic device, and specifically, may seal the front surface of the electronic device. Specifically, as the cured film seals the front surface of the electronic device, the refractive index is high while properties equivalent to those of existing devices are satisfied, and as a result, light efficiency of the electronic device (example: OLED) may increase.

Hereinafter, examples of the present disclosure will be described in detail so that those skilled in the art may readily carry out the present disclosure. However, these examples are for illustrative purposes only, and the scope of a right of the present disclosure is not limited by the following description.

### [Pre-Preparation Example: Preparation of Monomer, Initiator and Surfactant]

### Surface Tension

Surface tension of each of the monomers according to the following Table 1 was measured by a Du Nouy Ring or Wilhelmy Plate method at a temperature of 25° C. using a surface tensiometer (device name: K20 of KRUSS Scientific).

### Liquid Phase Refractive Index

A liquid phase refractive index of each of the monomers according to the following Table 1 was measured at 25° C. using RA-620 measurement device of KEM Kyoto Electronics Manufacturing Co., Ltd.

### Viscosity

Viscosity of each of the monomers according to the following Table 1 was measured at 25° C. using DV2T of AMETEK Brookfield.

TABLE 1

| | | | Surface | Liquid Phase | |
|---|---|---|---|---|---|
| | | | Tension | Refractive | Viscosity |
| Classification | Monomer | | (mN/m) | Index (nD²⁵) | (cP) |
| First | A-1 | 4-biphenyl methyl methacrylate | 42.4 | 1.58 | 25.9 |
| Monomer | A-2 | 1-naphthylmethyl acrylate | 38.9 | 1.59 | 28.0 |
| (Monomer | A-3 | 1-naphthyl acrylate | 37.8 | 1.60 | 30.6 |
| with High | A-4 | 2-phenylphenoxyethyl acrylate | 41.3 | 1.58 | 140 |
| Refractive | A-5 | 3-phenoxy benzyl acrylate | 41.0 | 1.57 | 14 |
| Index) | A-6 | Compound represented by the | 41.5 | 1.64 | 160 |
| | | following Chemical Formula 6-4 | | | |
| | | (n = 2, R = hydrogen) | | | |
| Second | B-1 | Triethylene glycol diacrylate | 38.1 | 1.46 | 14.2 |
| Monomer | B-2 | Tetraethylene glycol diacrylate | 39.3 | 1.46 | 22.6 |
| (Monomer | B-3 | 1,12-dodecanediol dimethacrylate | 32.8 | 1.47 | 12.0 |
| for | B-4 | Lauryl acrylate | 29.2 | 1.45 | 5.9 |
| Dilution) | B-5 | Isostearyl acrylate | 26.1 | 1.44 | 17.0 |
| | B-6 | 1,6-hexanediol diacrylate | 33.7 | 1.46 | 9.0 |

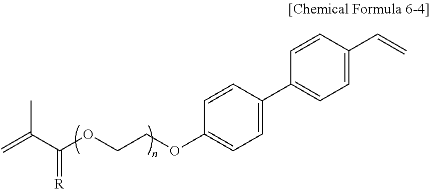

In addition, an initiator and a surfactant according to the following Table 2 were prepared.

TABLE 2
Component

| | | |
|---|---|---|
| Photoinitiator | C-1 | 2,4,6-trimethylbenzoyl-diphenyl- |
| | | phosphineoxide (Darocur ®TPO) |
| | C-2 | Ethyl(2,4,6-trimethylbenzoyl) |
| | | phenyphosphinate (Omnirad TPO-L) |
| Surfactant | D-1 | Dowsil ™FZ-2122 |
| | D-2 | Indusil ™ESS-110 |

### Preparation Example: Preparation of Photopolymerizable Composition

Photopolymerizable compositions were prepared in compositions and contents (unit: parts by weight) described in the following Tables 3 and 4.

TABLE 3

| | First Monomer | | Second Monomer | | Photoinitiator | | Surfactant | |
|---|---|---|---|---|---|---|---|---|
| Classification | Type | Content | Type | Content | Type | Content | Type | Content |
| Example 1 | A-1 | 55 | B-1 | 45 | C-2 | 3 | — | — |
| Example 2 | A-1 | 50 | B-1 | 50 | C-1 | 3 | — | — |
| Example 3 | A-2 | 80 | B-1 | 20 | C-1 | 3 | — | — |
| Example 4 | A-2 | 70 | B-1 | 30 | C-1 | 3 | — | — |
| Example 5 | A-2 | 60 | B-1 | 40 | C-1 | 3 | — | — |
| Example 6 | A-2 | 55 | B-1 | 45 | C-1 | 3 | — | — |
| Example 7 | A-2 | 50 | B-1 | 50 | C-1 | 3 | — | — |
| Example 8 | A-2 | 45 | B-1 | 55 | C-1 | 3 | — | — |
| Example 9 | A-3 | 80 | B-1 | 20 | C-1 | 3 | — | — |
| Example 10 | A-3 | 70 | B-1 | 30 | C-1 | 3 | — | — |
| Example 11 | A-3 | 60 | B-1 | 40 | C-1 | 3 | — | — |
| Example 12 | A-3 | 55 | B-1 | 45 | C-1 | 3 | — | — |
| Example 13 | A-3 | 50 | B-1 | 50 | C-1 | 3 | — | — |
| Example 14 | A-3 | 45 | B-1 | 55 | C-1 | 3 | — | — |
| Example 15 | A-3 | 40 | B-1 | 60 | C-1 | 3 | — | — |
| Example 16 | A-1 | 55 | B-2 | 45 | C-2 | 3 | — | — |
| Example 17 | A-1 | 50 | B-2 | 50 | C-1 | 3 | — | — |
| Example 18 | A-2 | 90 | B-2 | 10 | C-1 | 3 | — | — |
| Example 19 | A-2 | 80 | B-2 | 20 | C-1 | 3 | — | — |
| Example 20 | A-2 | 70 | B-2 | 30 | C-1 | 3 | — | — |
| Example 21 | A-2 | 60 | B-2 | 40 | C-1 | 3 | — | — |
| Example 22 | A-2 | 55 | B-2 | 45 | C-1 | 3 | — | — |
| Example 23 | A-2 | 50 | B-2 | 50 | C-1 | 3 | — | — |
| Example 24 | A-2 | 45 | B-2 | 55 | C-1 | 3 | — | — |
| Example 25 | A-2 | 30 | B-2 | 70 | C-1 | 3 | — | — |
| Example 26 | A-3 | 80 | B-2 | 20 | C-1 | 3 | — | — |
| Example 27 | A-3 | 70 | B-2 | 30 | C-1 | 3 | — | — |
| Example 28 | A-3 | 60 | B-2 | 40 | C-1 | 3 | — | — |
| Example 29 | A-3 | 55 | B-2 | 45 | C-1 | 3 | — | — |
| Example 30 | A-3 | 50 | B-2 | 50 | C-1 | 3 | — | — |
| Example 31 | A-3 | 45 | B-2 | 55 | C-1 | 3 | — | — |
| Example 32 | A-3 | 40 | B-2 | 60 | C-1 | 3 | — | — |
| Example 33 | A-2 | 80 | B-3 | 20 | C-1 | 3 | — | — |
| Example 34 | A-2 | 70 | B-3 | 30 | C-1 | 3 | — | — |
| Example 35 | A-2 | 60 | B-3 | 40 | C-1 | 3 | — | — |
| Example 36 | A-2 | 55 | B-3 | 45 | C-1 | 3 | — | — |
| Example 37 | A-2 | 50 | B-3 | 50 | C-1 | 3 | — | — |
| Example 38 | A-2 | 45 | B-3 | 55 | C-1 | 3 | — | — |
| Example 39 | A-3 | 80 | B-3 | 20 | C-1 | 3 | — | — |
| Example 40 | A-3 | 70 | B-3 | 30 | C-1 | 3 | — | — |
| Example 41 | A-3 | 60 | B-3 | 40 | C-1 | 3 | — | — |
| Example 42 | A-3 | 55 | B-3 | 45 | C-1 | 3 | — | — |
| Example 43 | A-3 | 50 | B-3 | 50 | C-1 | 3 | — | — |
| Example 44 | A-3 | 45 | B-3 | 55 | C-1 | 3 | — | — |
| Example 45 | A-3 | 40 | B-3 | 60 | C-1 | 3 | — | — |
| Example 46 | A-2 | 70 | B-6 | 30 | C-1 | 3 | — | — |
| Example 47 | A-2 | 60 | B-6 | 40 | C-1 | 3 | — | — |
| Example 48 | A-2 | 55 | B-6 | 45 | C-1 | 3 | — | — |
| Example 49 | A-3 | 70 | B-6 | 30 | C-1 | 3 | — | — |
| Example 50 | A-3 | 60 | B-6 | 40 | C-1 | 3 | — | — |
| Example 51 | A-3 | 50 | B-6 | 50 | C-1 | 3 | — | — |
| Example 52 | A-5 | 80 | B-1 | 20 | C-1 | 3 | — | — |
| Example 53 | A-5 | 70 | B-1 | 30 | C-1 | 3 | — | — |
| Example 54 | A-5 | 60 | B-1 | 40 | C-1 | 3 | — | — |
| Example 55 | A-5 | 80 | B-2 | 20 | C-1 | 3 | — | — |
| Example 56 | A-5 | 70 | B-2 | 30 | C-1 | 3 | — | — |
| Example 57 | A-2 | 55 | B-1 | 45 | C-1 | 5 | — | — |
| Example 58 | A-2 | 55 | B-1 | 45 | C-1 | 7 | — | — |
| Example 59 | A-2 | 55 | B-1 | 45 | C-1 | 10 | — | — |
| Example 60 | A-1 | 55 | B-1 | 45 | C-1 | 3 | D-1 | 0.03 |
| Example 61 | A-1 | 55 | B-1 | 45 | C-1 | 3 | D-2 | 0.03 |
| Example 62 | A-1 | 55 | B-1 | 45 | C-1 | 3 | D-1 | 0.05 |
| Example 63 | A-1 | 55 | B-1 | 45 | C-1 | 3 | D-2 | 0.05 |
| Example 64 | A-2 | 55 | B-1 | 45 | C-1 | 0.5 | — | — |
| Example 65 | A-2 | 55 | B-1 | 45 | C-1 | 2 | — | — |
| Example 66 | A-6 | 50 | B-1 | 50 | C-1 | 3 | — | — |
| Example 67 | A-6 | 40 | B-1 | 60 | C-1 | 3 | — | — |
| Example 68 | A-6 | 30 | B-1 | 70 | C-1 | 3 | — | — |

TABLE 4

| | First Monomer | | Second Monomer | | Photoinitiator | | Surfactant | |
|---|---|---|---|---|---|---|---|---|
| Classification | Type | Content | Type | Content | Type | Content | Type | Content |
| Example 69 | A-3 | 50 | B-1 | 50 | C-1 | 3 | — | — |
| Example 70 | A-3 | 50 | B-2 | 50 | C-1 | 3 | — | — |
| Example 71 | A-1 | 50 | B-1 | 50 | C-1 | 3 | — | — |
| Example 72 | A-2 | 55 | B-1 | 45 | C-1 | 0.1 | — | — |
| Example 73 | A-2 | 55 | B-1 | 45 | C-1 | 15 | — | — |
| Example 74 | A-2 | 55 | B-1 | 45 | C-1 | 20 | — | — |
| Example 75 | A-2 | 55 | B-1 | 45 | C-1 | 25 | — | — |
| Example 76 | A-2 | 55 | B-1 | 45 | C-1 | 30 | — | — |
| Example 77 | A-2 | 55 | B-1 | 45 | C-1 | 3 | D-1 | 20 |
| Example 78 | A-2 | 55 | B-1 | 45 | C-1 | 3 | D-2 | 20 |

TABLE 5

| | First Monomer | | Second Monomer | | Photoinitiator | | Surfactant | |
|---|---|---|---|---|---|---|---|---|
| Classification | Type | Content | Type | Content | Type | Content | Type | Content |
| Comparative | A-1 | 70 | B-3 | 30 | C-1 | 3 | — | — |
| Example 1 | | | | | | | | |
| Comparative | A-1 | 60 | B-3 | 40 | C-1 | 3 | — | — |
| Example 2 | | | | | | | | |
| Comparative | A-1 | 50 | B-3 | 50 | C-1 | 3 | — | — |
| Example 3 | | | | | | | | |
| Comparative | A-1 | 40 | B-3 | 60 | C-1 | 3 | — | — |
| Example 4 | | | | | | | | |
| Comparative | A-1 | 30 | B-3 | 70 | C-1 | 3 | — | — |
| Example 5 | | | | | | | | |
| Comparative | A-1 | 60 | B-3 | 30 | C-1 | 3 | — | — |
| Example 6 | A-4 | 10 | | | | | | |
| Comparative | A-1 | 50 | B-3 | 40 | C-1 | 3 | — | — |
| Example 7 | A-4 | 10 | | | | | | |
| Comparative | A-1 | 40 | B-3 | 50 | C-1 | 3 | — | — |
| Example 8 | A-4 | 10 | | | | | | |
| Comparative | A-1 | 30 | B-3 | 60 | C-1 | 3 | — | — |
| Example 9 | A-4 | 10 | | | | | | |
| Comparative | A-1 | 50 | B-3 | 30 | C-1 | 3 | — | — |
| Example 10 | A-4 | 20 | | | | | | |
| Comparative | A-1 | 40 | B-3 | 40 | C-1 | 3 | — | — |
| Example 11 | A-4 | 20 | | | | | | |
| Comparative | A-1 | 30 | B-3 | 50 | C-1 | 3 | — | — |
| Example 12 | A-4 | 20 | | | | | | |
| Comparative | A-1 | 20 | B-3 | 60 | C-1 | 3 | — | — |
| Example 13 | A-4 | 20 | | | | | | |
| Comparative | A-1 | 40 | B-3 | 30 | C-1 | 3 | — | — |
| Example 14 | A-4 | 30 | | | | | | |
| Comparative | A-1 | 30 | B-3 | 40 | C-1 | 3 | — | — |
| Example 15 | A-4 | 30 | | | | | | |
| Comparative | A-1 | 20 | B-3 | 50 | C-1 | 3 | — | — |
| Example 16 | A-4 | 30 | | | | | | |
| Comparative | A-1 | 10 | B-3 | 60 | C-1 | 3 | — | — |
| Example 17 | A-4 | 30 | | | | | | |
| Comparative | A-1 | 70 | B-3 | 25 | C-1 | 3 | — | — |
| Example 18 | | | B-4 | 5 | | | | |
| Comparative | A-1 | 60 | B-3 | 35 | C-1 | 3 | — | — |
| Example 19 | | | B-4 | 5 | | | | |
| Comparative | A-1 | 50 | B-3 | 45 | C-1 | 3 | — | — |
| Example 20 | | | B-4 | 5 | | | | |
| Comparative | A-1 | 40 | B-3 | 55 | C-1 | 3 | — | — |
| Example 21 | | | B-4 | 5 | | | | |
| Comparative | A-1 | 70 | B-3 | 25 | C-1 | 3 | — | — |
| Example 22 | | | B-5 | 5 | | | | |
| Comparative | A-1 | 60 | B-3 | 35 | C-1 | 3 | — | — |
| Example 23 | | | B-5 | 5 | | | | |
| Comparative | A-1 | 50 | B-3 | 45 | C-1 | 3 | — | — |
| Example 24 | | | B-5 | 5 | | | | |
| Comparative | A-1 | 40 | B-3 | 55 | C-1 | 3 | — | — |
| Example 25 | | | B-5 | 5 | | | | |
| Comparative | A-1 | 70 | B-6 | 30 | C-1 | 3 | — | — |
| Example 26 | | | | | | | | |
| Comparative | A-1 | 60 | B-6 | 40 | C-1 | 3 | — | — |
| Example 27 | | | | | | | | |
| Comparative | A-1 | 55 | B-6 | 45 | C-1 | 3 | — | — |
| Example 28 | | | | | | | | |
| Comparative | A-1 | 50 | B-6 | 50 | C-1 | 3 | — | — |
| Example 29 | | | | | | | | |
| Comparative | A-1 | 45 | B-6 | 55 | C-1 | 3 | — | — |
| Example 30 | | | | | | | | |
| Comparative | A-1 | 40 | B-6 | 60 | C-1 | 3 | — | — |
| Example 31 | | | | | | | | |
| Comparative | A-1 | 40 | B-3 | 20 | C-1 | 3 | — | — |
| Example 32 | | | B-4 | 10 | | | | |
| Comparative | A-1 | 70 | B-3 | 30 | C-1 | 3 | — | — |
| Example 33 | | | B-4 | 10 | | | | |
| Comparative | A-1 | 60 | B-3 | 40 | C-1 | 3 | — | — |
| Example 34 | | | B-4 | 10 | | | | |
| Comparative | A-1 | 50 | B-3 | 60 | C-1 | 3 | — | — |
| Example 35 | | | B-4 | 10 | | | | |
| Comparative | A-2 | 70 | B-4 | 30 | C-1 | 3 | — | — |
| Example 36 | | | | | | | | |
| Comparative | A-2 | 60 | B-4 | 40 | C-1 | 3 | — | — |
| Example 37 | | | | | | | | |
| Comparative | A-2 | 50 | B-4 | 50 | C-1 | 3 | — | — |
| Example 38 | | | | | | | | |
| Comparative | A-1 | 70 | B-1 | 15 | C-1 | 3 | — | — |
| Example 39 | | | B-3 | 15 | | | | |
| Comparative | A-1 | 60 | B-1 | 20 | C-1 | 3 | — | — |
| Example 40 | | | B-3 | 20 | | | | |
| Comparative | A-1 | 55 | B-1 | 15 | C-1 | 3 | — | — |
| Example 41 | | | B-3 | 30 | | | | |
| Comparative | A-1 | 55 | B-1 | 22.5 | C-1 | 3 | — | — |
| Example 42 | | | B-3 | 22.5 | | | | |
| Comparative | A-1 | 55 | B-1 | 30 | C-1 | 3 | — | — |
| Example 43 | | | B-3 | 15 | | | | |
| Comparative | A-1 | 60 | B-2 | 15 | C-1 | 3 | — | — |
| Example 44 | A-4 | 10 | B-3 | 15 | | | | |
| Comparative | A-1 | 50 | B-2 | 20 | C-1 | 3 | — | — |
| Example 45 | A-4 | 10 | B-3 | 20 | | | | |
| Comparative | A-1 | 45 | B-2 | 15 | C-1 | 3 | — | — |
| Example 46 | A-4 | 10 | B-3 | 30 | | | | |
| Comparative | A-1 | 45 | B-2 | 22.5 | C-1 | 3 | — | — |
| Example 47 | A-4 | 10 | B-3 | 22.5 | | | | |
| Comparative | A-1 | 45 | B-2 | 30 | C-1 | 3 | — | — |
| Example 48 | A-4 | 10 | B-3 | 15 | | | | |
| Comparative | A-5 | 70 | B-3 | 20 | C-1 | 3 | — | — |
| Example 49 | | | B-4 | 10 | | | | |
| Comparative | A-5 | 60 | B-3 | 30 | C-1 | 3 | — | — |
| Example 50 | | | B-4 | 10 | | | | |
| Comparative | A-5 | 70 | B-3 | 20 | C-1 | 3 | — | — |
| Example 51 | | | B-5 | 10 | | | | |
| Comparative | A-5 | 60 | B-3 | 30 | C-1 | 3 | — | — |
| Example 52 | | | B-5 | 10 | | | | |
| Comparative | A-5 | 70 | B-4 | 10 | C-1 | 3 | — | — |
| Example 53 | | | B-5 | 20 | | | | |
| Comparative | A-5 | 60 | B-4 | 10 | C-1 | 3 | — | — |
| Example 54 | | | B-5 | 30 | | | | |
| Comparative | A-5 | 70 | B-5 | 20 | C-1 | 3 | — | — |
| Example 55 | | | B-6 | 10 | | | | |
| Comparative | A-5 | 60 | B-5 | 30 | C-1 | 3 | — | — |
| Example 56 | | | B-6 | 10 | | | | |
| Comparative | A-1 | 50 | B-3 | 50 | C-1 | 3 | D-1 | 0.03 |
| Example 57 | | | | | | | | |
| Comparative | A-1 | 50 | B-3 | 50 | C-1 | 3 | D-2 | 0.03 |
| Example 58 | | | | | | | | |
| Comparative | A-1 | 50 | B-3 | 50 | C-1 | 3 | D-1 | 0.05 |
| Example 59 | | | | | | | | |
| Comparative | A-1 | 50 | B-3 | 50 | C-1 | 3 | D-2 | 0.05 |
| Example 60 | | | | | | | | |

### Experimental Example: Evaluation of Properties of Monomer, Photopolymerizable Composition and Optical Film

### 1) Deviation in Surface Tension Between Monomers

Surface tension of each of the monomers used for preparing each of the photopolymerizable compositions of the Examples and the Comparative Examples was measured by a Du Nouy Ring or Wilhelmy Plate method at 25° C. using a surface tensiometer (device name: K20 of KRUSS Scientific), and then a deviation of the second monomer with respect to the first monomer was calculated. Specifically, the deviation in surface tension between the monomers was calculated by the following Equation 1.

### Equation 1

Deviation in surface tension between monomers=|surface tension of first monomer-surface tension of second monomer|

### Evaluation Criteria

⊚: deviation in surface tension between monomers is 5.0 mN/m or less
O: deviation in surface tension between monomers is more than 5.0 mN/m and 8.0 mN/m or less
X: deviation in surface tension between monomers is more than 8.0 mN/m

### 2) Purity

Purity of each of the monomers used for preparing each of the photopolymerizable compositions of the Examples and the Comparative Examples was measured using liquid chromatography (device name: ACQUITY UPLC I-Class/ACQUITY UPLC BEH Shield RP18 Column of Waters Corporation) or gas chromatography (device name: HP7890B/DB-625 Column of Agilent Technologies, Inc./PerkinElmer, Inc.).

### Evaluation Criteria

⊚: purity is 98% or more
O: purity is 96% or more and less than 98%
Δ: purity is 94% or more and less than 96%
X: purity is less than 94%

### 3) Viscosity (Absolute Viscosity)

For each of the photopolymerizable compositions of the Examples and the Comparative Examples, absolute viscosity was measured at a temperature of 25° C. using a viscometer (device name: Viscometer of AMETEK Brookfield).

### Evaluation Criteria

O: viscosity is from 5 cP to 40 cP at 25° C.
X: viscosity is outside the range of 5 cP to 40 cP at 25° C.

### 4) Surface Tension

Surface tension of each of the photopolymerizable compositions of the Examples and the Comparative Examples was measured by a Du Nouy Ring or Wilhelmy Plate method at 25° C. using a surface tensiometer (device name: K20 of KRUSS Scientific).

### Evaluation Criteria

O: surface tension of photopolymerizable composition is from 20 mN/m to 60 mN/m
X: surface tension of photopolymerizable composition is outside the range of 20 mN/m to 60 mN/m

### 5) Refractive Index

After coating each of the photopolymerizable compositions of the Examples and the Comparative Examples on a silicon wafer, UV was irradiated thereon for 10 seconds at a dose of 1,500 mJ/cm² to form a cured film (optical film) having a thickness of 2 μm. A refractive index (wavelength of 450 nm) was measured for the cured film using an ellipsometer.

### Evaluation Criteria

O: measured value of single-film refractive index is 1.60 or more
Δ: measured value of single-film refractive index is from 1.58 to less than 1.60
X: measured value of single-film refractive index is less than 1.58

### 6) Transmittance

For the cured film formed in the same manner as in the method for measuring the refractive index, average transmittance at a wavelength of 380 nm to 780 nm was measured using a UV-vis spectrometer (device name: Cary4000 of Agilent Technologies, Inc.).

### Evaluation Criteria

O: average transmittance value is 97% or more
Δ: average transmittance value is 95% or more and less than 97%
X: average transmittance value is less than 95%

### 7) Haze

In order to measure haze of the cured film prepared in the same manner as in the method for measuring the refractive index, a haze meter (COH 400 of NIPPON DENSHOKU INDUSTRIES Co., Ltd.) was used.

### Evaluation Criteria

⊚: measured value of haze is less than 1.0%
O: measured value of haze is from 1.0% to 3.0%
X: measured value of haze is more than 3.0%

### 8) Inkjet Discharge Properties (A1, A2)

Each of the photopolymerizable compositions of the Examples and the Comparative Examples was discharged using an inkjet device (OmniJet Series of UniJet) equipped with a head (product name: KM1024i-SHE, Konica Minolta, Inc.) discharging a droplet quantified to 6 pico liters, and droplets discharged to a distance within 3 mm from the nozzle surface were photographed using a CCD camera and the angle of deviation from the nozzle was identified to measure first inkjet discharge properties (A1). Herein, A1 is defined as a parameter (unit: °) representing straightness of the discharged droplets during initial inkjet discharge.

After that, the photopolymerizable composition was allowed to stand by in the inkjet head for 3 days at a temperature of 40° C. or lower, and then second inkjet discharge properties (A2) were measured in the same manner as the first inkjet discharge properties (A1). Herein, A2 is defined as a parameter (unit: °) representing straightness of the discharged droplets during continuous discharge or inkjet discharge after a prolonged standby.

### Evaluation Criteria

⊚: for all the nozzles, inkjet discharge properties A1 and A2 values are 0.1° or less
O: for all the nozzles, inkjet discharge properties A1 and A2 values are more than 0.1° and 0.3° or less
Δ: for 50% of all the nozzles, inkjet discharge properties A1 and A2 values are 0.3° or less
X: for all the nozzles, inkjet discharge properties A1 and A2 values are more than 0.3°

### 9) Inkjet Droplet Parameter (IDP)

500 droplets of each of the photopolymerizable compositions of the Examples and the Comparative Examples were discharged on a substrate using an inkjet device (OmniJet Series of UniJet) equipped with a head (product name: KM1024i-SHE of Konica Minolta, Inc.) discharging a droplet quantified to 6 pico liters, and then an average distance between the formed droplets was measured using an optical microscope to evaluate first inkjet droplet properties (B1).

After that, for the photopolymerizable composition allowed to stand by in the inkjet head for 3 days at a temperature of 40° C. or lower, second inkjet droplet properties (B2) were evaluated in the same manner as the first inkjet droplet properties. After that, IDP was calculated using the following Equation 2. Herein, units of B1 and B2 are μm.

$$IDP \to \{ \frac{B 1 - B 2}{B 2} \} \times 100 \qquad [ Equation 2 ]$$

### Evaluation Criteria

O: inkjet droplet parameter (IDP) value is 99% or more
Δ: inkjet droplet parameter (IDP) value is 95% or more and less than 99%
X: inkjet droplet parameter (IDP) value is less than 95%

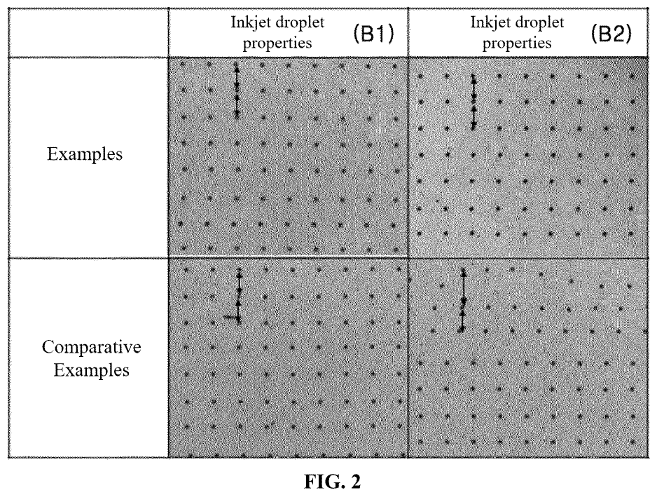

Meanwhile, FIG. 2 shows results of inkjet droplet parameters for the photopolymerizable compositions according to the Example and the Comparative Example. Referring to FIG. 2, it may be identified that the Example has excellent inkjet droplet properties compared to the Comparative Example.

TABLE 6

| | Deviation in | | | | | | | | | |
|---|---|---|---|---|---|---|---|---|---|---|
| | Surface | | | | | | | Inkjet | | Inkjet |
| | Tension | | | | | | | Discharge | | Droplet |
| | between | | Absolute | Surface | Refractive | | | Properties | | Parameter |
| Classification | Monomers | Purity | Viscosity | Tension | Index | Transmittance | Haze | A1 | A2 | (IDP) |
| Example 1 | ⊚ | ⊚ | ◯ | ◯ | ◯ | ◯ | ⊚ | ◯ | ◯ | ◯ |
| Example 2 | ⊚ | ⊚ | ◯ | ◯ | ◯ | ◯ | ⊚ | ◯ | ◯ | ◯ |
| Example 3 | ⊚ | ⊚ | ◯ | ◯ | ◯ | ◯ | ⊚ | ⊚ | ⊚ | ◯ |
| Example 4 | ⊚ | ⊚ | ◯ | ◯ | ◯ | ◯ | ⊚ | ⊚ | ⊚ | ◯ |
| Example 5 | ⊚ | ⊚ | ◯ | ◯ | ◯ | ◯ | ⊚ | ⊚ | ⊚ | ◯ |
| Example 6 | ⊚ | ⊚ | ◯ | ◯ | ◯ | ◯ | ⊚ | ⊚ | ⊚ | ◯ |
| Example 7 | ⊚ | ⊚ | ◯ | ◯ | ◯ | ◯ | ⊚ | ⊚ | ⊚ | ◯ |
| Example 8 | ⊚ | ⊚ | ◯ | ◯ | ◯ | ◯ | ⊚ | ⊚ | ⊚ | ◯ |
| Example 9 | ⊚ | ⊚ | ◯ | ◯ | ◯ | ◯ | ⊚ | ⊚ | ⊚ | ◯ |
| Example 10 | ⊚ | ⊚ | ◯ | ◯ | ◯ | ◯ | ⊚ | ⊚ | ⊚ | ◯ |
| Example 11 | ⊚ | ⊚ | ◯ | ◯ | ◯ | ◯ | ⊚ | ⊚ | ⊚ | ◯ |
| Example 12 | ⊚ | ⊚ | ◯ | ◯ | ◯ | ◯ | ⊚ | ⊚ | ⊚ | ◯ |
| Example 13 | ⊚ | ⊚ | ◯ | ◯ | ◯ | ◯ | ⊚ | ⊚ | ⊚ | ◯ |
| Example 14 | ⊚ | ⊚ | ◯ | ◯ | ◯ | ◯ | ⊚ | ⊚ | ⊚ | ◯ |
| Example 15 | ⊚ | ⊚ | ◯ | ◯ | ◯ | ◯ | ⊚ | ⊚ | ⊚ | ◯ |
| Example 16 | ⊚ | ⊚ | ◯ | ◯ | ◯ | ◯ | ⊚ | ◯ | ◯ | ◯ |
| Example 17 | ⊚ | ⊚ | ◯ | ◯ | ◯ | ◯ | ⊚ | ◯ | ◯ | ◯ |
| Example 18 | ⊚ | ⊚ | ◯ | ◯ | ◯ | ◯ | ⊚ | ⊚ | ⊚ | ◯ |
| Example 19 | ⊚ | ⊚ | ◯ | ◯ | ◯ | ◯ | ⊚ | ⊚ | ⊚ | ◯ |
| Example 20 | ⊚ | ⊚ | ◯ | ◯ | ◯ | ◯ | ⊚ | ⊚ | ⊚ | ◯ |
| Example 21 | ⊚ | ⊚ | ◯ | ◯ | ◯ | ◯ | ⊚ | ⊚ | ⊚ | ◯ |
| Example 22 | ⊚ | ⊚ | ◯ | ◯ | ◯ | ◯ | ⊚ | ⊚ | ⊚ | ◯ |
| Example 23 | ⊚ | ⊚ | ◯ | ◯ | ◯ | ◯ | ⊚ | ⊚ | ⊚ | ◯ |
| Example 24 | ⊚ | ⊚ | ◯ | ◯ | ◯ | ◯ | ⊚ | ⊚ | ⊚ | ◯ |
| Example 25 | ⊚ | ⊚ | ◯ | ◯ | ◯ | ◯ | ⊚ | ⊚ | ⊚ | ◯ |
| Example 26 | ⊚ | ⊚ | ◯ | ◯ | ◯ | ◯ | ⊚ | ⊚ | ⊚ | ◯ |
| Example 27 | ⊚ | ⊚ | ◯ | ◯ | ◯ | ◯ | ⊚ | ⊚ | ⊚ | ◯ |
| Example 28 | ⊚ | ⊚ | ◯ | ◯ | ◯ | ◯ | ⊚ | ⊚ | ⊚ | ◯ |
| Example 29 | ⊚ | ⊚ | ◯ | ◯ | ◯ | ◯ | ⊚ | ⊚ | ⊚ | ◯ |
| Example 30 | ⊚ | ⊚ | ◯ | ◯ | ◯ | ◯ | ⊚ | ⊚ | ⊚ | ◯ |
| Example 31 | ⊚ | ⊚ | ◯ | ◯ | ◯ | ◯ | ⊚ | ⊚ | ⊚ | ◯ |
| Example 32 | ⊚ | ⊚ | ◯ | ◯ | ◯ | ◯ | ⊚ | ⊚ | ⊚ | ◯ |
| Example 33 | ◯ | ⊚ | ◯ | ◯ | ◯ | ◯ | ⊚ | ◯ | ◯ | ◯ |
| Example 34 | ◯ | ⊚ | ◯ | ◯ | ◯ | ◯ | ⊚ | ◯ | ◯ | ◯ |
| Example 35 | ◯ | ⊚ | ◯ | ◯ | ◯ | ◯ | ⊚ | ◯ | ◯ | ◯ |
| Example 36 | ◯ | ⊚ | ◯ | ◯ | ◯ | ◯ | ⊚ | ◯ | ◯ | ◯ |
| Example 37 | ◯ | ⊚ | ◯ | ◯ | ◯ | ◯ | ⊚ | ◯ | ◯ | ◯ |
| Example 38 | ◯ | ⊚ | ◯ | ◯ | ◯ | ◯ | ⊚ | ◯ | ◯ | ◯ |
| Example 39 | ◯ | ⊚ | ◯ | ◯ | ◯ | ◯ | ⊚ | ◯ | ◯ | ◯ |
| Example 40 | ◯ | ⊚ | ◯ | ◯ | ◯ | ◯ | ⊚ | ◯ | ◯ | ◯ |
| Example 41 | ◯ | ⊚ | ◯ | ◯ | ◯ | ◯ | ⊚ | ◯ | ◯ | ◯ |
| Example 42 | ◯ | ◯ | ◯ | ◯ | ◯ | ◯ | ⊚ | ◯ | ◯ | ◯ |
| Example 43 | ◯ | ◯ | ◯ | ◯ | ◯ | ◯ | ⊚ | ◯ | ◯ | ◯ |
| Example 44 | ◯ | ◯ | ◯ | ◯ | ◯ | ◯ | ⊚ | ◯ | ◯ | ◯ |
| Example 45 | ◯ | ◯ | ◯ | ◯ | ◯ | ◯ | ⊚ | ◯ | ◯ | ◯ |
| Example 46 | ◯ | ⊚ | ◯ | ◯ | ◯ | ◯ | ⊚ | ◯ | ◯ | ◯ |
| Example 47 | ◯ | ⊚ | ◯ | ◯ | ◯ | ◯ | ⊚ | ◯ | ◯ | ◯ |
| Example 48 | ◯ | ⊚ | ◯ | ◯ | ◯ | ◯ | ⊚ | ◯ | ◯ | ◯ |
| Example 49 | ◯ | ◯ | ◯ | ◯ | ◯ | ◯ | ⊚ | ◯ | ◯ | ◯ |
| Example 50 | ◯ | ◯ | ◯ | ◯ | ◯ | ◯ | ⊚ | ◯ | ◯ | ◯ |
| Example 51 | ◯ | ◯ | ◯ | ◯ | ◯ | ◯ | ⊚ | ◯ | ◯ | ◯ |
| Example 52 | ⊚ | ⊚ | ◯ | ◯ | ◯ | ◯ | ⊚ | ⊚ | ⊚ | ◯ |
| Example 53 | ⊚ | ⊚ | ◯ | ◯ | ◯ | ◯ | ⊚ | ⊚ | ⊚ | ◯ |
| Example 54 | ⊚ | ⊚ | ◯ | ◯ | ◯ | ◯ | ⊚ | ⊚ | ⊚ | ◯ |
| Example 55 | ⊚ | ⊚ | ◯ | ◯ | ◯ | ◯ | ⊚ | ⊚ | ⊚ | ◯ |
| Example 56 | ⊚ | ⊚ | ◯ | ◯ | ◯ | ◯ | ⊚ | ⊚ | ⊚ | ◯ |
| Example 57 | ⊚ | ⊚ | ◯ | ◯ | ◯ | ◯ | ⊚ | ⊚ | ⊚ | ◯ |
| Example 58 | ⊚ | ⊚ | ◯ | ◯ | ◯ | ◯ | ⊚ | ⊚ | ⊚ | ◯ |
| Example 59 | ⊚ | ⊚ | ◯ | ◯ | ◯ | ◯ | ⊚ | ⊚ | ⊚ | ◯ |
| Example 60 | ⊚ | ⊚ | ◯ | ◯ | ◯ | ◯ | ⊚ | ⊚ | ⊚ | ◯ |
| Example 61 | ⊚ | ⊚ | ◯ | ◯ | ◯ | ◯ | ⊚ | ⊚ | ⊚ | ◯ |
| Example 62 | ⊚ | ⊚ | ◯ | ◯ | ◯ | ◯ | ⊚ | ⊚ | ⊚ | ◯ |
| Example 63 | ⊚ | ⊚ | ◯ | ◯ | ◯ | ◯ | ⊚ | ⊚ | ⊚ | ◯ |
| Example 64 | ⊚ | ⊚ | ◯ | ◯ | ◯ | ◯ | ⊚ | ⊚ | ⊚ | ◯ |
| Example 65 | ⊚ | ⊚ | ◯ | ◯ | ◯ | ◯ | ⊚ | ⊚ | ⊚ | ◯ |
| Example 66 | ⊚ | ◯ | ◯ | ◯ | ◯ | ◯ | ⊚ | ◯ | ◯ | ◯ |
| Example 67 | ⊚ | ◯ | ◯ | ◯ | ◯ | ◯ | ⊚ | ◯ | ◯ | ◯ |
| Example 68 | ⊚ | ◯ | ◯ | ◯ | ◯ | ◯ | ⊚ | ◯ | ◯ | ◯ |

TABLE 7

| | Deviation in | | | | | | | | | |
|---|---|---|---|---|---|---|---|---|---|---|
| | Surface | | | | | | | Inkjet | | Inkjet |
| | Tension | | | | | | | Discharge | | Droplet |
| | between | | Absolute | Surface | Refractive | | | Properties | | Parameter |
| Classification | Monomers | Purity | Viscosity | Tension | Index | Transmittance | Haze | A1 | A2 | (IDP) |
| Example 69 | ◯ | Δ | ◯ | ◯ | ◯ | ◯ | ⊚ | Δ | Δ | Δ |
| Example 70 | ◯ | Δ | ◯ | ◯ | ◯ | ◯ | ⊚ | Δ | Δ | Δ |
| Example 71 | ◯ | Δ | ◯ | ◯ | ◯ | ◯ | ⊚ | Δ | Δ | Δ |
| Example 72 | ⊚ | ⊚ | ◯ | ◯ | Δ | Δ | Δ | ⊚ | ⊚ | ◯ |
| Example 73 | ⊚ | ⊚ | ◯ | ◯ | Δ | ◯ | ⊚ | ◯ | Δ | Δ |
| Example 74 | ⊚ | ⊚ | ◯ | ◯ | ◯ | ◯ | ⊚ | ◯ | Δ | Δ |
| Example 75 | ⊚ | ⊚ | ◯ | ◯ | ◯ | ◯ | ⊚ | Δ | Δ | Δ |
| Example 76 | ⊚ | ⊚ | ◯ | ◯ | ◯ | ◯ | ⊚ | Δ | Δ | Δ |
| Example 77 | ⊚ | ⊚ | ◯ | ◯ | Δ | ◯ | ⊚ | Δ | Δ | Δ |
| Example 78 | ⊚ | ⊚ | ◯ | ◯ | Δ | ◯ | ⊚ | Δ | Δ | Δ |

TABLE 8

| | Deviation in | | | | | | | | | |
|---|---|---|---|---|---|---|---|---|---|---|
| | Surface | | | | | | | Inkjet | | Inkjet |
| | Tension | | | | | | | Discharge | | Droplet |
| | between | | Absolute | Surface | Refractive | | | Properties | | Parameter |
| Classification | Monomers | Purity | Viscosity | Tension | Index | Transmittance | Haze | A1 | A2 | (IDP) |
| Comparative | X | ⊚ | ◯ | ◯ | ◯ | ◯ | ⊚ | Δ | X | X |
| Example 1 | | | | | | | | | | |
| Comparative | X | ⊚ | ◯ | ◯ | ◯ | ◯ | ⊚ | Δ | X | X |
| Example 2 | | | | | | | | | | |
| Comparative | X | ⊚ | ◯ | ◯ | ◯ | ◯ | ⊚ | Δ | X | X |
| Example 3 | | | | | | | | | | |
| Comparative | X | ⊚ | ◯ | ◯ | X | ◯ | ⊚ | Δ | X | X |
| Example 4 | | | | | | | | | | |
| Comparative | X | ⊚ | ◯ | ◯ | X | ◯ | ⊚ | Δ | X | X |
| Example 5 | | | | | | | | | | |
| Comparative | X | ⊚ | ◯ | ◯ | ◯ | ◯ | ⊚ | Δ | X | X |
| Example 6 | | | | | | | | | | |
| Comparative | X | ⊚ | ◯ | ◯ | ◯ | ◯ | ⊚ | Δ | X | X |
| Example 7 | | | | | | | | | | |
| Comparative | X | ⊚ | ◯ | ◯ | X | ◯ | ⊚ | Δ | X | X |
| Example 8 | | | | | | | | | | |
| Comparative | X | ⊚ | ◯ | ◯ | X | ◯ | ⊚ | Δ | X | X |
| Example 9 | | | | | | | | | | |
| Comparative | X | ⊚ | ◯ | ◯ | ◯ | ◯ | ⊚ | Δ | X | X |
| Example 10 | | | | | | | | | | |
| Comparative | X | ⊚ | ◯ | ◯ | ◯ | ◯ | ⊚ | Δ | X | X |
| Example 11 | | | | | | | | | | |
| Comparative | X | ⊚ | ◯ | ◯ | X | ◯ | ⊚ | Δ | X | X |
| Example 12 | | | | | | | | | | |
| Comparative | X | ⊚ | ◯ | ◯ | X | ◯ | ⊚ | Δ | X | X |
| Example 13 | | | | | | | | | | |
| Comparative | X | ⊚ | ◯ | ◯ | ◯ | ◯ | ⊚ | Δ | X | X |
| Example 14 | | | | | | | | | | |
| Comparative | X | ⊚ | ◯ | ◯ | ◯ | ◯ | ⊚ | Δ | X | X |
| Example 15 | | | | | | | | | | |
| Comparative | X | ⊚ | ◯ | ◯ | X | ◯ | ⊚ | Δ | X | X |
| Example 16 | | | | | | | | | | |
| Comparative | X | ⊚ | ◯ | ◯ | X | ◯ | ⊚ | Δ | X | X |
| Example 17 | | | | | | | | | | |
| Comparative | X | ⊚ | ◯ | ◯ | ◯ | ◯ | ⊚ | X | X | X |
| Example 18 | | | | | | | | | | |
| Comparative | X | ⊚ | ◯ | ◯ | ◯ | ◯ | ⊚ | X | X | X |
| Example 19 | | | | | | | | | | |
| Comparative | X | ⊚ | ◯ | ◯ | X | ◯ | ⊚ | X | X | X |
| Example 20 | | | | | | | | | | |
| Comparative | X | ⊚ | ◯ | ◯ | X | ◯ | ⊚ | X | X | X |
| Example 21 | | | | | | | | | | |
| Comparative | X | ⊚ | ◯ | ◯ | ◯ | ◯ | ⊚ | X | X | X |
| Example 22 | | | | | | | | | | |
| Comparative | X | ⊚ | ◯ | ◯ | ◯ | ◯ | ⊚ | X | X | X |
| Example 23 | | | | | | | | | | |
| Comparative | X | ⊚ | ◯ | ◯ | X | ◯ | ⊚ | X | X | X |
| Example 24 | | | | | | | | | | |
| Comparative | X | ⊚ | ◯ | ◯ | X | ◯ | ⊚ | X | X | X |
| Example 25 | | | | | | | | | | |
| Comparative | X | ⊚ | ◯ | ◯ | ◯ | ◯ | ⊚ | Δ | X | X |
| Example 26 | | | | | | | | | | |
| Comparative | X | ⊚ | ◯ | ◯ | ◯ | ◯ | ⊚ | Δ | X | X |
| Example 27 | | | | | | | | | | |
| Comparative | X | ⊚ | ◯ | ◯ | ◯ | ◯ | ⊚ | Δ | X | X |
| Example 28 | | | | | | | | | | |
| Comparative | X | ⊚ | ◯ | ◯ | ◯ | ◯ | ⊚ | Δ | X | X |
| Example 29 | | | | | | | | | | |
| Comparative | X | ⊚ | ◯ | ◯ | X | ◯ | ⊚ | Δ | X | X |
| Example 30 | | | | | | | | | | |
| Comparative | X | ⊚ | ◯ | ◯ | X | ◯ | ⊚ | Δ | X | X |
| Example 31 | | | | | | | | | | |
| Comparative | X | ⊚ | ◯ | ◯ | ◯ | ◯ | ⊚ | X | X | X |
| Example 32 | | | | | | | | | | |
| Comparative | X | ⊚ | ◯ | ◯ | ◯ | ◯ | ⊚ | X | X | X |
| Example 33 | | | | | | | | | | |
| Comparative | X | ⊚ | ◯ | ◯ | X | ◯ | ⊚ | X | X | X |
| Example 34 | | | | | | | | | | |
| Comparative | X | ⊚ | ◯ | ◯ | X | ◯ | ⊚ | X | X | X |
| Example 35 | | | | | | | | | | |
| Comparative | X | ⊚ | ◯ | ◯ | ◯ | ◯ | ⊚ | X | X | X |
| Example 36 | | | | | | | | | | |
| Comparative | X | ⊚ | ◯ | ◯ | ◯ | ◯ | ⊚ | X | X | X |
| Example 37 | | | | | | | | | | |
| Comparative | X | ⊚ | ◯ | ◯ | ◯ | ◯ | ⊚ | X | X | X |
| Example 38 | | | | | | | | | | |
| Comparative | X | ⊚ | ◯ | ◯ | ◯ | ◯ | ⊚ | X | X | X |
| Example 39 | | | | | | | | | | |
| Comparative | X | ⊚ | ◯ | ◯ | ◯ | ◯ | ⊚ | X | X | X |
| Example 40 | | | | | | | | | | |
| Comparative | X | ⊚ | ◯ | ◯ | ◯ | ◯ | ⊚ | X | X | X |
| Example 41 | | | | | | | | | | |
| Comparative | X | ⊚ | ◯ | ◯ | ◯ | ◯ | ⊚ | X | X | X |
| Example 42 | | | | | | | | | | |
| Comparative | X | ⊚ | ◯ | ◯ | ◯ | ◯ | ⊚ | X | X | X |
| Example 43 | | | | | | | | | | |
| Comparative | X | ⊚ | ◯ | ◯ | ◯ | ◯ | ⊚ | X | X | X |
| Example 44 | | | | | | | | | | |
| Comparative | X | ⊚ | ◯ | ◯ | ◯ | ◯ | ⊚ | X | X | X |
| Example 45 | | | | | | | | | | |
| Comparative | X | ⊚ | ◯ | ◯ | ◯ | ◯ | ⊚ | X | X | X |
| Example 46 | | | | | | | | | | |
| Comparative | X | ⊚ | ◯ | ◯ | ◯ | ◯ | ⊚ | X | X | X |
| Example 47 | | | | | | | | | | |
| Comparative | X | ⊚ | ◯ | ◯ | ◯ | ◯ | ⊚ | X | X | X |
| Example 48 | | | | | | | | | | |
| Comparative | X | ⊚ | ◯ | ◯ | ◯ | ◯ | ⊚ | X | X | X |
| Example 49 | | | | | | | | | | |
| Comparative | X | ⊚ | ◯ | ◯ | ◯ | ◯ | ⊚ | X | X | X |
| Example 50 | | | | | | | | | | |
| Comparative | X | ⊚ | ◯ | ◯ | ◯ | ◯ | ⊚ | X | X | X |
| Example 51 | | | | | | | | | | |
| Comparative | X | ⊚ | ◯ | ◯ | ◯ | ◯ | ⊚ | X | X | X |
| Example 52 | | | | | | | | | | |
| Comparative | X | ⊚ | ◯ | ◯ | ◯ | ◯ | ⊚ | X | X | X |
| Example 53 | | | | | | | | | | |
| Comparative | X | ⊚ | ◯ | ◯ | ◯ | ◯ | ⊚ | X | X | X |
| Example 54 | | | | | | | | | | |
| Comparative | X | ⊚ | ◯ | ◯ | ◯ | ◯ | ⊚ | X | X | X |
| Example 55 | | | | | | | | | | |
| Comparative | X | ⊚ | ◯ | ◯ | ◯ | ◯ | ⊚ | X | X | X |
| Example 56 | | | | | | | | | | |
| Comparative | X | ⊚ | ◯ | ◯ | ◯ | ◯ | ⊚ | ◯ | Δ | X |
| Example 57 | | | | | | | | | | |
| Comparative | X | ⊚ | ◯ | ◯ | X | ◯ | ⊚ | ◯ | Δ | X |
| Example 58 | | | | | | | | | | |
| Comparative | X | ⊚ | ◯ | ◯ | X | ◯ | ⊚ | ◯ | Δ | X |
| Example 59 | | | | | | | | | | |
| Comparative | X | ⊚ | ◯ | ◯ | X | ◯ | ⊚ | ◯ | Δ | X |
| Example 60 | | | | | | | | | | |

Preferred embodiments of the present disclosure have been described in detail hereinbefore, however, the scope of a right of the present disclosure is not limited thereto, and various modified and improved forms made by those skilled in the art using the basic concept of the present disclosure defined in the claims also fall within the scope of a right of the present disclosure.

1. A photopolymerizable composition comprising:
a first monomer having a first photocurable functional group;
a second monomer having a second photocurable functional group; and
an initiator,
wherein the first and second monomers satisfy the following Equation 1:
$$C = \vert A - B \vert \leq 8. mN / m \qquad [ Equation 1 ]$$
in Equation 1,
C is an absolute value (mN/m) of a deviation of surface tension of the second monomer with respect to surface tension of the first monomer;
A is surface tension (mN/m) of the first monomer at 25° C.; and
B is surface tension (mN/m) of the second monomer at 25° C.

2. The photopolymerizable composition of claim 1, wherein the first monomer has surface tension of 43 mN/m or less.

3. The photopolymerizable composition of claim 1, wherein the first monomer includes a structure represented by the following Chemical Formula 1: 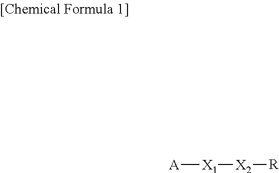
in Chemical Formula 1,
A includes at least one structure among a substituted or unsubstituted aryl group; a substituted or unsubstituted aromatic heteroring; and a substituted or unsubstituted bicyclic structure;
X₁ is a direct bond; or a divalent linking group having 1 to 20 carbon atoms including or not including at least one oxygen atom;
X₂ is a direct bond; or a divalent linking group having 1 to 20 carbon atoms including or not including at least one oxygen atom; and
R is the first photocurable functional group.

4. The photopolymerizable composition of claim 3, wherein, in Chemical Formula 1, A is a substituted or unsubstituted aryl group having 6 to 14 carbon atoms, X₁ is a direct bond, and X₂ is a divalent linking group having 1 to 10 carbon atoms including or not including at least one oxygen atom.

5. The photopolymerizable composition of claim 1, wherein the first monomer includes at least one selected from the group consisting of benzyl (meth)acrylate, phenoxyethyl (meth)acrylate, phenoxybenzyl (meth)acrylate, O-phenyl phenoxyethyl (meth)acrylate, biphenyl (meth)acrylate, biphenylethyl (meth)acrylate, and compounds represented by the following Chemical Formulae 2 to 9: 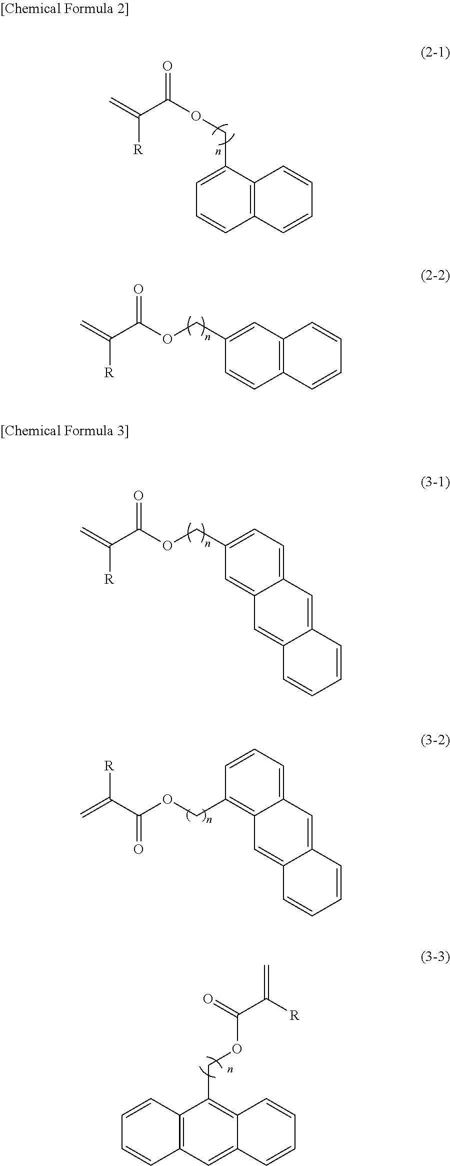 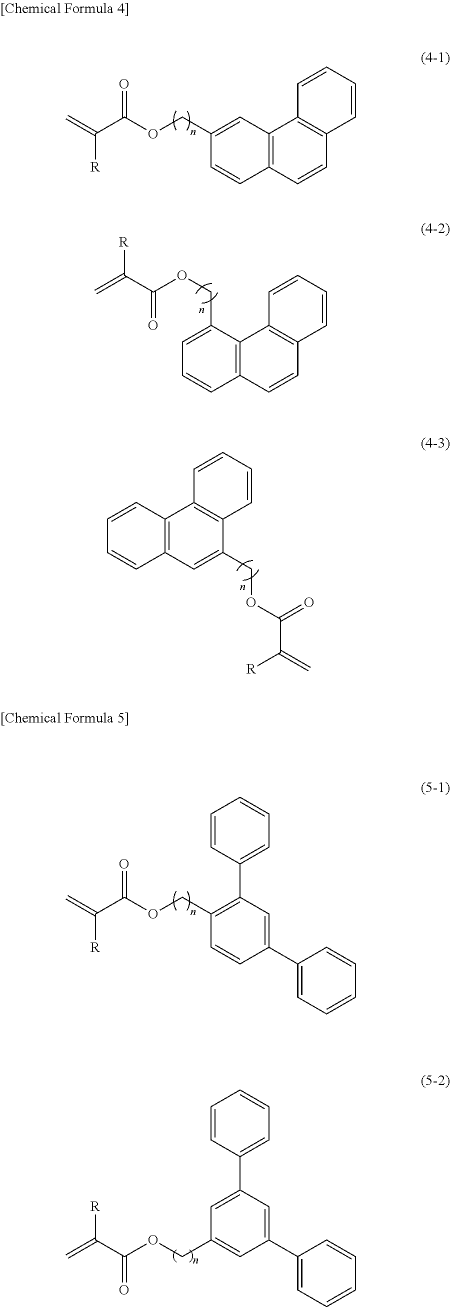 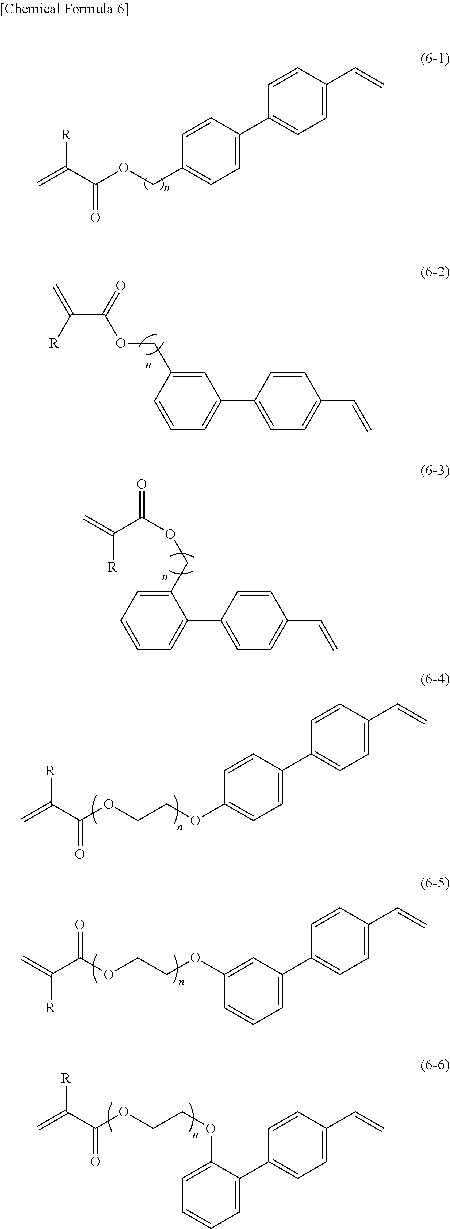 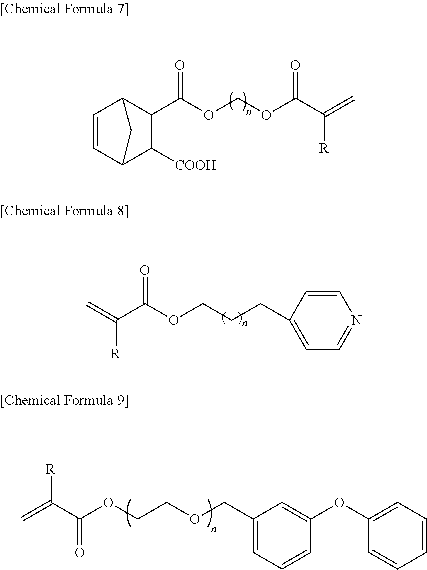
in Chemical Formulae 2 to 9,
R are each independently a hydrogen atom or an alkyl group having 1 to 4 carbon atoms; and
n are each independently an integer of 0 to 10.

6. The photopolymerizable composition of claim 1, wherein the first monomer has purity of 95% or higher.

7. The photopolymerizable composition of claim 1, wherein the first monomer has purity of 98% or higher.

8. The photopolymerizable composition of claim 1, wherein a content of the first monomer is from 30 parts by weight to 90 parts by weight with respect to 100 parts by weight of all the monomers including the first monomer and the second monomer.

9. The photopolymerizable composition of claim 1, wherein the second monomer includes a structure represented by the following Chemical Formula 10: 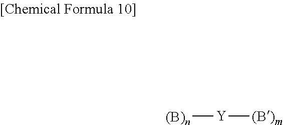
in Chemical Formula 10,
B and B′ include the second photocurable functional groups that are the same as or different from each other;
Y includes a substituted or unsubstituted hydrocarbon structure having 4 to 50 carbon atoms, including or not including at least one oxygen atom;
n and m are an integer of 0 to 2; and
n+m satisfies 1 or 2.

10. The photopolymerizable composition of claim 9, wherein, in Chemical Formula 10, Y includes, as an aliphatic or aromatic structure having 4 to 50 carbon atoms, an alkylene oxide group having 6 or more carbon atoms, an alkylene group having 6 or more carbon atoms, or an alkenylene group having 6 or more carbon atoms.

11. The photopolymerizable composition of claim 1, wherein the second monomer includes at least one type selected from the group consisting of ethylene glycol di(meth)acrylate, propylene glycol di(meth)acrylate, neopentyl glycol di(meth)acrylate, diethylene glycol di(meth)acrylate, triethylene glycol di(meth)acrylate, tetraethylene glycol di(meth)acrylate, butanediol di(meth)acrylate, pentanediol di(meth)acrylate, 1,6-hexanediol di(meth)acrylate, 1,12-dodecanediol di(meth)acrylate, isostearyl acrylate, lauryl acrylate, 1,6-hexanediol ethoxylate di(meth)acrylate and a compound represented by the following Chemical Formula 11: 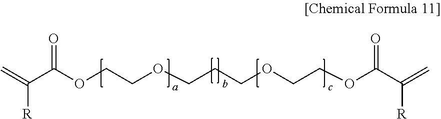
in Chemical Formula 11,
R are each independently hydrogen or an alkyl group; and
a, b and c are integers that satisfy a+b+c=1 to 20.

12. The photopolymerizable composition of claim 11, wherein, in Chemical Formula 11, b is 0, and a and c are an integer of 1 to 20.

13. The photopolymerizable composition of claim 1, wherein a content of the initiator is from 0.5 parts by weight to 10 parts by weight with respect to 100 parts by weight of all the monomers including the first monomer and the second monomer.

14. The photopolymerizable composition of claim 1, wherein the initiator includes a radical initiator.

15. The photopolymerizable composition of claim 1, further comprising at least one type selected from the group consisting of a surfactant; an amine enhancer; and a photosensitizer.

16. The photopolymerizable composition of claim 15, wherein a content of the surfactant is from 0.001 parts by weight to 20 parts by weight with respect to 100 parts by weight of all the monomers including the first monomer and the second monomer.

17. The photopolymerizable composition of claim 1, which is in a solvent-free form.

18. The photopolymerizable composition of claim 1, which has absolute viscosity measured at 25° C. of 5 cP to 40 cP.

19. An electronic device comprising a cured film in which the photopolymerizable composition of claim 1 is cured.
